(19) United States
(12) Patent Application Publication
(10) Pub. No.: US 2024/0097089 A1
(43) Pub. Date: Mar. 21, 2024

(54) DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR); No Kyung PARK, Yongin-si (KR)

(73) Assignee: Samsung Display Co., LTD., Yongin-si (KR)

(21) Appl. No.: 18/465,272

(22) Filed: Sep. 12, 2023

(30) Foreign Application Priority Data
Sep. 15, 2022 (KR) 10-2022-0116569

(51) Int. Cl. H01L 33/62; H01L 25/075; H01L 25/16; H01L 27/12; H01L 33/38

(52) U.S. Cl. CPC H01L 33/62; H01L 25/0753; H01L 25/167; H01L 27/124; H01L 33/382

(57) ABSTRACT

A display device may include pixels disposed on a substrate. Each of the pixels may include a first conductive layer including first, second, and third conductive patterns, first and second insulating layers that are stacked on each other on the first conductive layer, a second conductive layer including a first power line, a second power line, and a connection pattern, third and fourth insulating layers that are stacked on each other on the second conductive layer, a third conductive layer including first alignment electrodes and second alignment electrodes, and a light emitting element disposed on the first and second alignment electrodes. At least one of the first alignment electrodes may be electrically connected to at least one of the first, second, and third conductive patterns.

### CROSS-REFERENCE TO RELATED APPLICATION(S)

This application claims priority to and benefits of Korean Patent Application No. 10-2022-0116569 under 35 U.S.C. § 119(a), filed on Sep. 15, 2022 in the Korean Intellectual Property Office, the entire contents of which are incorporated herein by reference.

### BACKGROUND

### 1. Technical Field

This disclosure relates to a display device.

### 2. Description of the Related Art

Recently, as interest in information displays increases, research and development of display devices is continuously conducted.

### SUMMARY

Embodiments provide a display device capable of improving reliability.

In accordance with an aspect of the disclosure, there is provided a display device that may include pixels disposed on a substrate. Each of the pixels may include a first conductive layer including a first conductive pattern, a second conductive pattern, and a third conductive pattern that are disposed on the substrate to be spaced apart from each other, a first insulating layer and a second insulating layer that are sequentially stacked on each other on the first conductive layer, a second conductive layer disposed on the second insulating layer, the second conductive layer including a first power line, a second power line, and a connection pattern, which are spaced apart from each other, a third insulating layer and a fourth insulating layer that are sequentially stacked on each other on the second conductive layer, a third conductive layer disposed on the fourth insulating layer, the third conductive layer including first alignment electrodes and second alignment electrodes, which are spaced apart from each other, and a light emitting element disposed on the first and second alignment electrodes. At least one of the first alignment electrodes may be electrically connected to at least one of the first conductive pattern, the second conductive pattern, and the third conductive pattern.

The first insulating layer and the second insulating layer may include a first through-hole, a second through-hole, and a third through-hole exposing the first conductive pattern, the second conductive pattern, and the third conductive pattern. The third insulating layer and the fourth insulating layer may include a first via hole exposing the first power line, a second via hole exposing the second power line, and a third via hole exposing the connection pattern.

The first power line may be disposed on the first conductive pattern, thereby overlapping the first conductive pattern, the second power line may be disposed on the second conductive pattern, thereby overlapping the second conductive pattern, and the connection pattern may be disposed on the third conductive pattern, thereby overlapping the third conductive pattern.

The first power line may be electrically connected to the first conductive pattern while penetrating the first through-hole, the second power line may be electrically connected to the second conductive pattern while penetrating the second through-hole, and the connection pattern may be electrically connected to the third conductive pattern while penetrating the third through-hole.

Each of the pixels may include a first sub-pixel, a second sub-pixel, and a third sub-pixel. Each of the first sub-pixel, the second sub-pixel, and the third sub-pixel may include one first alignment electrode among the first alignment electrodes and two second alignment electrodes with the one first alignment electrode interposed therebetween among the second electrodes.

An area of the one first alignment electrode of the second sub-pixel may be electrically connected to the first power line while penetrating the first via hole, and another area of the one first alignment electrode of the second sub-pixel may be electrically connected to the connection pattern while penetrating the third via hole. One second alignment electrode adjacent to the second sub-pixel among the two second alignment electrodes of the first sub-pixel may be electrically connected to the second power line while penetrating the second via hole.

The one second alignment electrode may be electrically connected one of the two second alignment electrodes of the second sub-pixel.

The one first alignment electrode of the second sub-pixel may be electrically connected to the third conductive pattern through the third via hole, the connection pattern, and the third through-hole.

The third conductive pattern may include a first part extending in a first direction and a second part extending in a second direction different from the direction in which the first part extends. The one first alignment electrode in the third via hole may have a shape corresponding to the first part and the second part of the third conductive pattern.

Each of the first sub-pixel, the second sub-pixel, and the third sub-pixel may include a lower metal pattern configured with the first conductive layer and an upper electrode configured with the second conductive layer, the upper electrode being disposed on the lower metal pattern with the first and second insulating layers interposed therebetween. The lower metal pattern and the upper electrode may constitute a storage capacitor.

The third conductive pattern may be integrally formed with the lower metal pattern of the second sub-pixel.

The one first alignment electrode of the second sub-pixel may be electrically connected to the first conductive pattern through the first via hole, the first power line, and the first through-hole.

The one first alignment electrode in the first via hole may have a shape corresponding to the first conductive pattern.

The first conductive pattern may include a first part extending in a first direction and a second part extending in a second direction different from the first direction.

The one second alignment electrode of the first sub-pixel may be electrically connected to the second conductive pattern through the second via hole, the second power line, and the second through-hole.

The one second alignment electrode in the second via hole may have a shape corresponding to the second conductive pattern.

The second conductive pattern may include a first part extending in a first direction and a second part extending in a second direction different from the first direction.

Each of the first conductive pattern and the second conductive pattern may be a floating pattern.

Each of the pixels may further include a bank disposed on the first alignment electrodes and the second alignment electrodes, a fifth insulating layer disposed over the bank, the fifth insulating layer including a first contact hole exposing an area of the first alignment electrode and a second contact hole exposing an area of the second alignment electrode, an insulating pattern disposed on the fifth insulating layer, the insulating pattern exposing a first end portion and a second end portion of the light emitting element, and a fourth conductive layer including a first electrode and a second electrode, which are disposed on the insulating pattern to be spaced apart from each other. The first electrode may be electrically connected to the first alignment electrode while penetrating the first contact hole, and the second electrode may be electrically connected to the second alignment electrode while penetrating the second contact hole.

In accordance with another aspect of the disclosure, there is provided a display device that may include a substrate including a display area and a non-display area, and at least one pixel disposed in the display area. The at least one pixel may include a first sub-pixel, a second sub-pixel, and a third sub-pixel each including an emission area and a non-emission area. The pixel may include a first insulating layer, a second insulating layer, a third insulating layer, and a fourth insulating layer that are sequentially stacked on each other on the substrate, a first conductive pattern, a second conductive pattern, and a third conductive pattern that are disposed between the substrate and the first insulating layer, the first conductive pattern, the second conductive pattern, and the third conductive pattern being spaced apart from each other, a semiconductor layer disposed between the first insulating layer and the second insulating layer, a first power line, a second power line, and a connection pattern, that are disposed between the second insulating layer and the third insulating layer, the first power line, the second power line, and the connection pattern, being spaced apart from each other, a first alignment electrode and a second alignment electrode disposed on the fourth insulating layer, the first alignment electrode and the second alignment electrode being spaced apart from each other, a light emitting element disposed on the first alignment electrode and the second alignment electrode in at least the emission area, and a first electrode and a second electrode disposed on the light emitting element, the first electrode and the second electrode being electrically connected to the light emitting element. The first insulating layer and the second insulating layer may include a first through-hole exposing the first conductive pattern, a second through-hole exposing the second conductive pattern, and a third through-hole exposing the third conductive pattern. The third insulating layer and the fourth insulating layer may include a first via hole exposing the first power line, a second via hole exposing the second power line, and a third via hole exposing the connection pattern. The first alignment electrode may be electrically connected to at least one of the first conductive pattern, the second conductive pattern, and the third conductive pattern.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a light emitting element in accordance with an embodiment of the disclosure.

FIG. 2 is a schematic cross-sectional view of the light emitting element shown in FIG. 1.

FIG. 3 is a schematic plan view illustrating a display device in accordance with an embodiment of the disclosure.

FIG. 4 is a schematic cross-sectional view of a display panel shown in FIG. 3.

FIG. 5 is a schematic circuit diagram illustrating an electrical connection relationship of components included in the pixels shown in FIG. 3.

FIG. 6 is a schematic plan view illustrating a pixel circuit layer of a pixel in accordance with an embodiment of the disclosure.

FIG. 7 is a schematic cross-sectional view taken along line I-I′ shown in FIG. 6.

FIG. 8 is a schematic plan view illustrating a display element layer of a pixel in accordance with an embodiment of the disclosure.

FIG. 9 is a schematic plan view illustrating a first sub-pixel shown in FIG. 8.

FIG. 10 is a schematic cross-sectional view taken along line II-II′ shown in FIG. 9.

FIG. 11 is a schematic cross-sectional view taken along line III-III′ shown in FIG. 9.

FIG. 12 is a schematic plan view illustrating a pixel in which an alignment electrode is included in the pixel shown in FIG. 6.

FIG. 13A is a schematic enlarged view illustrating portion EA1 shown in FIG. 12.

FIG. 13b is a schematic image obtained by enlarging area A shown in FIG. 13A, using an electron microscope.

FIG. 14 is a schematic cross-sectional view taken along line IV-IV′ shown in FIG. 12.

FIGS. 15A and 15B are schematic enlarged views illustrating portion EA2 shown in FIG. 12.

FIGS. 16A and 16B are schematic enlarged views illustrating portion EA3 shown in FIG. 12.

### DETAILED DESCRIPTION OF THE EMBODIMENTS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Further, an expression that an element such as a layer, region, substrate or plate is placed “on” or “above” another element indicates not only a case where the element is placed “directly on” or “just above” the other element but also a case where a further element is interposed between the element and the other element. An expression that an element such as a layer, region, substrate or plate is placed “beneath” or “below” another element indicates not only a case where the element is placed “directly beneath” or “just below” the other element but also a case where a further element is interposed between the element and the other element.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween. It will be understood that the terms “connected to” or “coupled to” may include a physical or electrical connection or coupling.

In the following description, singular forms in the disclosure are intended to include the plural forms as well, unless the context clearly indicates otherwise.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

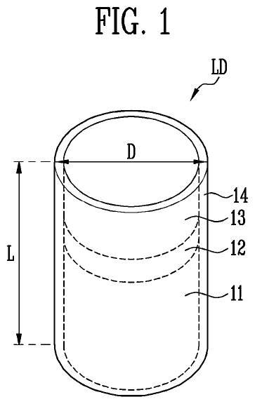

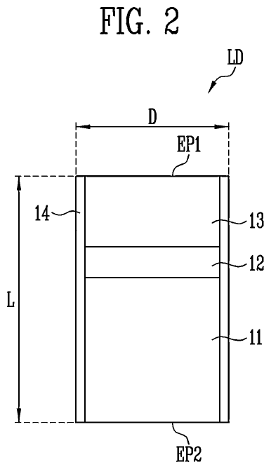

FIG. 1 is a schematic perspective view illustrating a light emitting element LD in accordance with an embodiment of the disclosure. FIG. 2 is a schematic cross-sectional view of the light emitting element LD shown in FIG. 1.

Referring to FIGS. 1 and 2, the light emitting element LD may include a first semiconductor layer 11, a second semiconductor layer 13, and an active layer 12 interposed between the first and second semiconductor layers 11 and 13. In an example, the light emitting element LD may be implemented with a light emitting stack structure (or stack pattern) in which the first semiconductor layer 11, the active layer 12, and the second semiconductor layer 13 are sequentially stacked on each other. The kind and/or shape of the light emitting element LD is not limited to the embodiment shown in FIG. 1.

The light emitting element LD may be provided in a shape extending in a direction. In case that assuming that an extending direction of the light emitting element LD is a length direction, the light emitting element LD may include a first end portion EP1 and a second end portion EP2, which face each other along the length direction. One semiconductor layer selected from the first semiconductor layer 11 and the second semiconductor layer 13 may be disposed at the first end portion EP1 of the light emitting element LD, and the other semiconductor layer selected from the first semiconductor layer 11 and the second semiconductor layer 13 may be disposed at the second end portion EP2 of the light emitting element LD. In an example, the second semiconductor layer 13 may be disposed at the first end portion EP1 of the light emitting element LD, and the first semiconductor layer 11 may be disposed at the second end portion EP2 of the corresponding light emitting element LD.

The light emitting element LD may be provided in various shapes. In an example, the light emitting element LD may have a rod-like shape, a bar-like shape, a pillar-like shape, or the like, which is long in its length direction (e.g., its aspect ratio is greater than 1) as shown in FIG. 1. In another example, the light emitting element LD may have a rod-like shape, a bar-like shape, a pillar-like shape, or the like, which is short in its length direction (e.g., its aspect ratio is smaller than 1). In still another example, the light emitting element LD may have a rod-like shape, a bar-like shape, a pillar-like shape, or the like, of which aspect ratio is 1.

The light emitting element LD may include, for example, a light emitting diode (LED) manufactured small enough to have a diameter D and/or a length L to a degree of a nano scale (or nanometers) to a micro scale (micrometers).

In case that the light emitting element LD is long in its length direction (e.g., its aspect ratio is greater than 1), the diameter D of the light emitting element LD may be about 0.5 μm to about 6 μm, and the length L of the light emitting element LD may be about 1 μm to about 10 μm. However, the diameter D and the length L of the light emitting element LD are not limited thereto, and the size of the light emitting element LD may be changed to accord with requirement conditions (or design conditions) of a lighting device or a self-luminous display device, to which the light emitting element LD is applied.

The first semiconductor layer 11 may include, for example, at least one n-type semiconductor layer. For example, the first semiconductor layer 11 may include at least one semiconductor material among InAlGaN, GaN, AlGaN, InGaN, AlN, and InN, and include an n-type semiconductor layer doped with a first conductive dopant (or n-type dopant) such as Si, Ge and/or Sn. However, the material constituting the first semiconductor layer 11 is not limited thereto. The first semiconductor layer 11 may be configured with various materials.

The active layer 12 may be formed on the first semiconductor layer 11, and may be formed in a single or multiple quantum well structure. In an example, in case that the active layer 12 is formed in the multiple quantum well structure, a barrier layer (not shown), a strain reinforcing layer, and a well layer, which constitute one unit, may be periodically and repeatedly stacked in the active layer 12. However, the structure of the active layer 12 is not limited to the above-described embodiment.

The active layer 12 may emit light having a wavelength of 400 nm to 900 nm, and use a double hetero structure. In an embodiment, a clad layer doped with a conductive dopant may be formed on the top and/or the bottom of the active layer 12 along the length L direction of the light emitting element LD. In an example, the clad layer may be formed as an AlGaN layer or InAIGaN layer. In some embodiments, a material such as AlGaN or AlInGaN may be used to form the active layer 12. The active layer 12 may be configured with various materials. The active layer 12 may include a first surface in contact with the first semiconductor layer 11 and a second surface in contact with the second semiconductor layer 13.

In case that an electric field having a predetermined or selected voltage or more is applied to both end portions of the light emitting element LD, the light emitting element LD may emit light as electron-hole pairs are combined in the active layer 12. The light emission of the light emitting element LD may be controlled by using such a principle, so that the light emitting element LD can be used as a light source (or light emitting source) for various light emitting devices, including a pixel of a display device.

The second semiconductor layer 13 may be formed on the second surface of the active layer 12, and may include a semiconductor layer having a type different from that of the first semiconductor layer 11. In an example, the second semiconductor layer 13 may include at least one p-type semiconductor material. For example, the second semiconductor layer 13 may include at least one semiconductor material among InAIGaN, GaN, AlGaN, InGaN, AlN, and InN, and include a p-type semiconductor layer doped with a second conductive dopant (or p-type dopant) such as Mg, Zn, Ca, Sr and/or Ba. However, the material constituting the second semiconductor layer 13 is not limited thereto. The second semiconductor layer 13 may be configured with various materials.

In an embodiment, the first semiconductor layer 11 and the second semiconductor layer 13 may have different thicknesses in the length L direction of the light emitting element LD. In an example, the first semiconductor layer 11 may have a thickness relatively thicker than that of the second semiconductor layer 13 along the length L direction of the light emitting element LD.

Although a case where each of the first semiconductor layer 11 and the second semiconductor layer 13 is configured with one layer is illustrated in FIGS. 1 and 2, the disclosure is not limited thereto. In an embodiment, each of the first semiconductor layer 11 and the second semiconductor layer 13 may further include at least one layer, for example, a clad layer and/or a Tensile Strain Barrier Reducing (TSBR) layer according to the material of the active layer 12. The TSBR layer may be a strain reducing layer disposed between semiconductor layers having different lattice structures to perform a buffering function for reducing a lattice constant difference. The TSBR may be configured with a p-type semiconductor layer such as p-GAInP, p-AlInP and/or p-AlGaInP, but the disclosure is not limited thereto.

In some embodiments, the light emitting element LD may further include a contact electrode (not shown) (hereinafter, referred to as a “first contact electrode”) disposed on the top of the second semiconductor layer 13, in addition to the first semiconductor layer 11, the active layer 12, and the second semiconductor layer 13, which are described above. In other embodiments, the light emitting element LD may further include another contact electrode (not shown) (hereinafter, referred to as a “second contact electrode”) disposed at one end of the first semiconductor layer 11.

Each of the first and second contact electrodes may be an ohmic contact electrode, but the disclosure is not limited thereto. In some embodiments, each of the first and second contact electrodes may be a Schottky contact electrode. The first and second contact electrodes may include a conductive material. For example, the first and second contact electrodes may include an opaque metal using one or mixture of chromium (Cr), titanium (Ti), aluminum (Al), gold (Au), nickel (Ni), and any oxide or alloy thereof, but the disclosure is not limited thereto. In some embodiments, the first and second contact electrodes may include a transparent conductive oxide such as indium tin oxide (ITO), indium zinc oxide (IZO), zinc oxide (ZnOₓ), indium gallium zinc oxide (IGZO), and/or indium tin zinc oxide (ITZO). The zinc oxide (ZnOₓ) may be zinc oxide (ZnO) and/or zinc peroxide (ZnO₂).

Materials respectively included in the first and second contact electrodes may be identical to or different from each other. The first and second contact electrodes may be substantially transparent or translucent. Accordingly, light generated in the light emitting element LD can be emitted to the outside of the light emitting element LD by passing through the first and second contact electrodes. In some embodiments, in case that light generated in the light emitting element LD does not pass through the first and second contact electrodes and is emitted to the outside of the light emitting element LD through an area except both the end portions, for example, the first and second end portions EP1 and EP2 of the light emitting element LD, the first and second contact electrodes may include an opaque metal.

In an embodiment, the light emitting element LD may further include an insulating film 14. However, in some embodiments, the insulating film 14 may be omitted, and be provided to cover only portions of the first semiconductor layer 11, the active layer 12, and the second semiconductor layer 13.

The insulating film 14 can prevent an electrical short circuit which may occur in case that the active layer 12 is in contact with a conductive material in addition to the first semiconductor layer 11 and the second semiconductor layer 13. Also, the insulating film 14 minimizes a surface defect of the light emitting element LD, thereby improving the lifetime and light emission efficiency of the light emitting element LD. Also, in case that multiple light emitting elements LD are densely disposed, the insulating film 14 can prevent an unwanted short circuit which may occur between the light emitting elements LD. Whether the insulative film is provided is not limited as long as the active layer 12 can prevent occurrence of a short circuit with external conductive material.

The insulating film 14 may be provided in a shape entirely surrounding the outer circumference of the light emitting stack structure including the first semiconductor layer 11, the active layer 12, and the second semiconductor layer 13.

Although a case where the insulating film 14 is provided in a shape entirely surrounding the outer circumference of each of the first semiconductor layer 11, the active layer 12, and the second semiconductor layer 13 is described in the above-described embodiment, the disclosure is not limited thereto. In some embodiments, in case that the light emitting element LD includes the first contact electrode, the insulating film 14 may entirely surround the outer circumference of each of the first semiconductor layer 11, the active layer 12, the second semiconductor layer 13, and the first contact electrode. In other embodiments, the insulating film 14 may not entirely surround the outer circumference of the first contact electrode, or may surround only a portion of the outer circumference of the first contact electrode and may not surround the other of the outer circumference of the first contact electrode. In some embodiments, in case that the first contact electrode is disposed at the first end portion EP1 of the light emitting element LD and the second contact electrode is disposed at the second end portion EP2 of the light emitting element LD, the insulating film 14 may expose at least one area of each of the first and second contact electrodes.

The insulating film 14 may include a transparent insulating material. For example, the insulating film 14 may include at least one insulating material selected from the group consisting of silicon oxide (SiOₓ), silicon nitride (SiNₓ), silicon oxynitride (SiOₓ N_{y}), aluminum oxide (AlOₓ), titanium dioxide (TiO₂), hafnium oxide (HfOₓ), titanium strontium oxide (SrTiOₓ), cobalt oxide (CoₓO_{y}), magnesium oxide (MgO), zinc oxide (ZnO), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InxOy:H, niobium oxide (NbₓO_{y}), magnesium fluoride (MgFₓ), aluminum fluoride (AlFₓ), Alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), vanadium nitride (VN), and the like. However, the disclosure is not limited thereto, and various materials having insulating properties may be used as the material of the insulating film 14.

The insulating film 14 may be provided in the form of a single layer or be provided in the form of a multi-layer including at least two layers. In an example, in case that the insulating film 14 may be configured as a double layer including a first layer and a second layer, which are sequentially stacked on each other, the first layer and the second layer may be made of different materials (or substances), and be formed through different processes. In some embodiments, the first layer and the second layer may be formed of the same material through a continuous process.

In some embodiments, the light emitting element LD may be implemented with a light emitting pattern having a core-shell structure. The first semiconductor layer 11 may be located (disposed) at a core, i.e., in the middle (or center) of the light emitting element LD, the active layer 12 may be provided and/or formed in a shape surrounding the outer circumference of the first semiconductor layer 11, and the second semiconductor layer 13 may be provided and/or formed in a shape surrounding the active layer 12. Also, the light emitting element LD may further include a contact electrode (not shown) surrounding at least one side of the second semiconductor layer 13. In some embodiments, the light emitting element LD may further include an insulative film which is provided on the outer circumference of the light emitting pattern having the core-shell structure and includes a transparent insulating material. The light emitting element LD implemented with the light emitting pattern having the core-shell structure may be manufactured through a growth process.

The above-described light emitting element LD may be used as a light emitting source (or light source) for various display devices. The light emitting element LD may be manufactured through a surface treatment process. For example, in case that multiple light emitting elements LD are mixed in a liquid solution (or solvent) to be supplied to each pixel area (for example, an emission area of each pixel or an emission area of each sub-pixel), each light emitting element LD may be surface-treated such that the light emitting elements LD are not unequally condensed in the solution but equally dispersed in the solution.

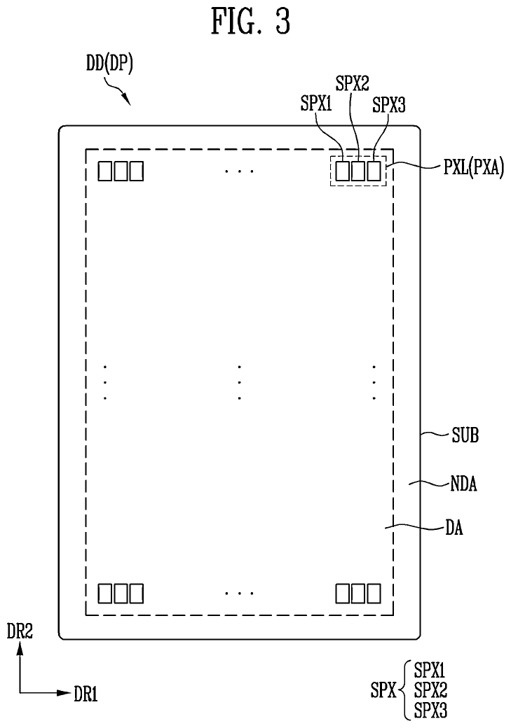

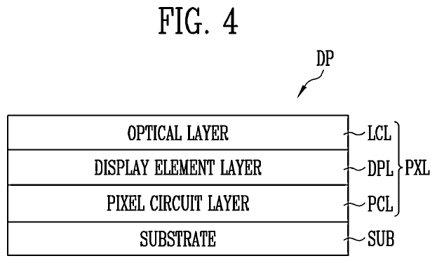

FIG. 3 is a schematic plan view illustrating a display device DD in accordance with an embodiment of the disclosure. FIG. 4 is a schematic cross-sectional view of a display panel DP shown in FIG. 3.

In FIGS. 3 and 4, for convenience of description, a structure of the display device DD, particularly, the display panel DP provided in the display device DD is briefly illustrated based on a display area DA in which an image is displayed.

The disclosure may be applied as long as the display device DD is an electronic device in which a display surface is applied to at least one surface thereof, such as a smartphone, a television, a tablet personal computer (PC), a mobile phone, a video phone, an electronic book reader, a desktop PC, a laptop PC, a netbook computer, a workstation, a server, a personal digital assistant (PDA), a portable multimedia player (PMP), an MP3 player, a medical device, a camera, or a wearable device.

Referring to FIGS. 1 to 4, the display device DD may be classified into a passive matrix type display device and an active matrix type display device according to a method of driving the light emitting element LD. In an example, in case that the display device DD is implemented as the active matrix type display device, the pixels PXL may include a driving transistor for controlling an amount of current supplied to the light emitting element LD, a switching transistor for transferring a data signal to the driving transistor, and the like.

The display panel DP (or the display device DD) may include a substrate SUB and the pixels PXL provided on the substrate SUB.

The substrate SUB may include a transparent insulating material to enable light to be transmitted therethrough. The substrate SUB may be a rigid substrate or a flexible substrate.

The rigid substrate may be, for example, a glass substrate, a quartz substrate, a glass ceramic substrate, and/or a crystalline glass substrate.

The flexible substrate may be a film substrate or a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

An area of the substrate SUB may be provided as the display area DA such that the pixels PXL are disposed therein, and another area of the substrate SUB may be provided as a non-display area NDA. In an example, the substrate SUB may include the display area DA including pixel areas PXA in which the respective pixels PXL are disposed and the non-display area NDA disposed at the periphery of the display area DA (or adjacent to the display area DA).

The non-display area NDA may be located adjacent to the display area DA. The non-display area NDA may be provided at at least one side of the display area DA. In an example, the non-display area NDA may surround a circumference (or edge) of the display area DA. A line part electrically connected to each pixel PXL and a driver which is electrically connected to the line part and drives the pixel PXL may be provided in the non-display area NDA.

Each of the pixels PXL may be provided in the display area DA of the substrate SUB. In an embodiment, the pixels PXL may be arranged in a stripe arrangement structure or the like in the display area DA, but the disclosure is not limited thereto.

Each pixel PXL may include a pixel circuit layer PCL, a display element layer DPL, and an optical layer LCL, which are located on the substrate SUB.

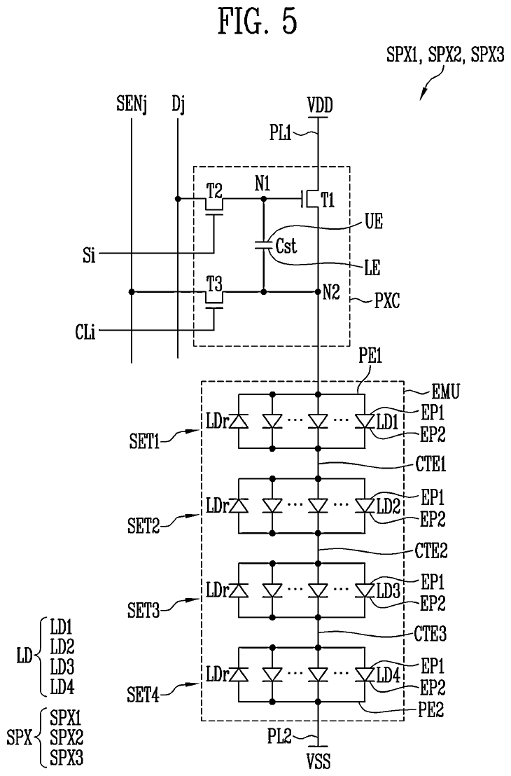

A pixel circuit (see “PXC” shown in FIG. 5) which is provided on the substrate SUB and includes transistors and signal lines electrically connected to the transistors may be disposed in the pixel circuit layer PCL. Each transistor may have, for example, a form in which a semiconductor layer, a gate electrode, a first terminal, and a second terminal are sequentially stacked on each other with an insulating layer interposed therebetween. The semiconductor layer may include amorphous silicon, poly-silicon, low temperature poly-silicon, an organic semiconductor, and/or an oxide semiconductor. The gate electrode, the first terminal (or source electrode), and the second terminal (or drain electrode) may include at least one of aluminum (Al), copper (Cu), titanium (Ti), and molybdenum (Mo), but the disclosure is not limited thereto. Also, the pixel circuit layer PCL may include at least one insulating layer.

The display element layer DPL may be disposed on the pixel circuit layer PCL. An emission component (see “EMU” shown in FIG. 5) including the light emitting element LD emitting light may be located in the display element layer DPL. A first alignment electrode (or first alignment line) and a second alignment electrode (or second alignment line), which are spaced apart from each other, may be disposed in the emission component EMU. The light emitting element LD may be disposed between the first alignment electrode and the second alignment electrode.

The optical layer LCL may be disposed on the display element layer DPL. The optical layer LCL may convert light emitted from the light emitting element LD into light having excellent color reproducibility and release the converted light, so that the light emission efficiency of each pixel PXL is improved. In some embodiments, the optical layer LCL may include a color conversion layer, a color filter, and the like, but the disclosure is not limited thereto.

FIG. 5 is a schematic circuit diagram illustrating an electrical connection relationship of components included in the pixels PXL shown in FIG. 3.

For example, FIG. 5 illustrates an electrical connection relationship of components included in a pixel PXL (or sub-pixel SPX) applicable to an active matrix type display device in accordance with an embodiment. However, the connection relationship of the components of each pixel PXL (or sub-pixel SPX) is not limited thereto.

Referring to FIGS. 1 to 5, the sub-pixel SPX (or pixel PXL) may include an emission component EMU which generates light with a luminance corresponding to a data signal. Also, the sub-pixel SPX may selectively further include a pixel circuit PXC for driving the emission component EMU.

For example, the emission component EMU may include a first electrode PE1 (or first pixel electrode) electrically connected to a first driving power source VDD through a first power line PL1, a second electrode PE2 (or second pixel electrode) electrically connected to a second driving power source VSS through a second power line PL2, and light emitting elements LD electrically connected between the first and second electrodes PE1 and PE2. The first driving power source VDD and the second driving power source VSS may have different potentials such that the light emitting elements LD can emit light. In an example, the first driving power source VDD may be set as a high-potential power source, and the second driving power source VSS may be set as a low-potential power source.

In an embodiment, the emission component EMU may include at least one serial stage. Each serial stage may include a pair of electrodes (for example, two electrodes) and at least one light emitting element LD electrically connected in a forward direction between the pair of electrodes. The number of serial stages constituting the emission component EMU and the number of light emitting elements LD constituting each serial stage are not particularly limited. In an example, numbers of light emitting elements LD constituting the respective serial stages may be equal to or different from each other, and a number of light emitting elements LD is not particularly limited.

For example, the emission component unit EMU may include a first serial stage SET1 including at least one first light emitting element LD1, a second serial stage SET2 including at least one second light emitting element LD2, a third serial stage SET3 including at least one third light emitting element LD3, and a fourth serial stage SET4 including at least one fourth light emitting element LD4.

The first serial stage SET1 may include the first electrode PE1, a first intermediate electrode CTE1 (or first bridge electrode), and at least one first light emitting element LD1 electrically connected between the first electrode PE1 and the first intermediate electrode CTE1. Each first light emitting element LD1 may be electrically connected in the forward direction between the first electrode PE1 and the first intermediate electrode CTE1. For example, a first end portion EP1 of the first light emitting element LD1 may be electrically connected to the first electrode PE1, and a second end portion EP2 of the first light emitting element LD1 may be electrically connected to the first intermediate electrode CTE1.

The second serial stage SET2 may include the first intermediate electrode CTE1, a second intermediate electrode CTE2 (or second bridge electrode), and at least one second light emitting element LD2 electrically connected between the first and second intermediate electrodes CTE1 and CTE2. Each second light emitting element LD2 may be electrically connected in the forward direction between the first and second intermediate electrodes CTE1 and CTE2. For example, a first end portion EP1 of the second light emitting element LD2 may be electrically connected to the first intermediate electrode CTE1, and a second end portion EP2 of the second light emitting element LD2 may be electrically connected to the second intermediate electrode CTE2.

The third serial stage SET3 may include the second intermediate electrode CTE2, a third intermediate electrode CTE3 (or third bridge electrode), and at least one third light emitting element LD3 electrically connected between the second and third intermediate electrodes CTE2 and CTE3. Each third light emitting element LD3 may be electrically connected in the forward direction between the second and third intermediate electrodes CTE2 and CTE3. For example, a first end portion EP1 of the third light emitting element LD3 may be electrically connected to the second intermediate electrode CTE2, and a second end portion EP2 of the third light emitting element LD3 may be electrically connected to the third intermediate electrode CTE3.

The fourth serial stage SET4 may include the third intermediate electrode CTE3, the second electrode PE2, and at least one fourth light emitting element LD4 electrically connected between the third intermediate electrode CTE3 and the second electrode PE2. Each fourth light emitting element LD4 may be electrically connected in the forward direction between the third intermediate electrode CTE3 and the second electrode PE2. For example, a first end portion EP1 of the fourth light emitting element LD4 may be electrically connected to the third intermediate electrode CTE3, and a second end portion EP2 of the fourth light emitting element LD4 may be electrically connected to the second electrode PE2.

A first electrode, for example, the first electrode PE1 of the emission component EMU may be an anode electrode of the emission component EMU. A last electrode, for example, the second electrode PE2 of the emission component EMU may be a cathode electrode of the emission component EMU.

In case that light emitting elements LD are electrically connected in a series/parallel structure, power efficiency can be improved as compared with a case where light emitting elements LD of which number is equal to that of the above-described light emitting elements LD are electrically connected only in parallel. In the sub-pixel SPX in which the light emitting elements LD are electrically connected in the series/parallel structure, although a short defect or the like may occur in some serial stages, a predetermined or selected luminance can be expressed through light emitting elements LD of the other serial stage. Hence, the probability that a dark spot defect will occur in the sub-pixel SPX can be reduced. However, the disclosure is not limited thereto, and the emission component EMU may be configured by connecting the light emitting elements LD only in series or by connecting the light emitting elements LD only in parallel.

Each of the light emitting element LD may include a first end portion EP1 (for example, a p-type end portion) electrically connected to the first driving power source VDD via at least one electrode (for example, the first electrode PE1), the pixel circuit PXC, and/or the first power line PL1, and a second end portion EP2 (for example, an n-type end portion) electrically connected to the second driving power source VSS via at least another electrode (for example, the second electrode PE2) and the second power line PL2. For example, the light emitting elements LD may be electrically connected in the forward direction between the first driving power source VDD and the second driving power source VSS. The light emitting elements LD electrically connected in the forward direction may constitute effective light sources of the emission component EMU.

In some embodiments, the emission component EMU may further include at least one ineffective light source, for example, at least one reverse light emitting element LDr in addition to the light emitting elements LD constituting the respective effective light sources.

The light emitting elements LD of the emission component EMU may emit light with a luminance corresponding to a driving current supplied through the corresponding pixel circuit PXC. For example, during each frame period, the pixel circuit PXC may supply, to the emission component EMU, a driving current corresponding to a grayscale value of a corresponding frame data. The driving current supplied to the emission component EMU may be divided to flow through each of the light emitting elements LD. Accordingly, while each light emitting element LD may emit light with a luminance corresponding to a current flowing therethrough, the emission component EMU can emit light with the luminance corresponding to the driving current.

The pixel circuit PXC may be electrically connected to a scan line Si and a data line Dj of the corresponding sub-pixel SPX. In an example, in case that a sub-pixel SPX is disposed on an ith row and a jth column of the display area DA, a pixel circuit PXC of the sub-pixel SPX may be electrically connected to an ith scan line Si and a jth data line Dj of the display area DA. Also, the pixel circuit PXC may be electrically connected to an ith control line CLi and a jth sensing line SENj.

The above-described pixel circuit PXC may include first to third transistors T1, T2, and T3 and a storage capacitor Cst.

The first transistor T1 may be a driving transistor for controlling a driving current applied to the emission component EMU, and may be electrically connected between the first driving power source VDD and the emission component EMU. Specifically, a first terminal of the first transistor T1 may be electrically connected to the first driving power source VDD through the first power line PL1, a second terminal of the first transistor T1 may be electrically connected to a second node N2, and a gate electrode of the first transistor T1 may be electrically connected to a first node N1. The first transistor T1 may control an amount of driving current applied from the first driving power source VDD to the emission component EMU through the second node N2 according to a voltage applied to the first node N1. In an embodiment, the first terminal of the first transistor T1 may be a drain electrode, and the second terminal of the first transistor T1 may be a source electrode. However, the disclosure is not limited thereto. In some embodiments, the first terminal may be the source electrode, and the second terminal may be the drain electrode.

The second transistor T2 may be a switching transistor which selects a sub-pixel SPX in response to a scan signal and activates the sub-pixel SPX, and may be electrically connected between the data line Dj (for example, the jth data line) and the first node N1. A first terminal of the second transistor T2 may be electrically connected to the data line Dj, a second terminal of the second transistor T2 may be electrically connected to the first node N1, and a gate electrode of the second transistor T2 may be electrically connected to the scan line Si (for example, the ith scan line). The first terminal and the second terminal of the second transistor T2 may be different terminals. For example, in case that the first terminal is a drain electrode, and the second terminal may be a source electrode.

The second transistor T2 may be turned on in case that the scan signal having a gate-on voltage (for example, a high level voltage) is supplied from the scan line Si, to electrically connect the data line Dj and the first node N1 to each other. The first node N1 may be a point at the second terminal of the second transistor T2 and the gate electrode of the first transistor T1 may be electrically connected to each other, and the second transistor T2 may transfer a data signal to the gate electrode of the first transistor T1.

The third transistor T3 may connect the first transistor T1 to the sensing line SENj (for example, the jth sensing line), to acquire a sensing signal through the sensing line SENj and to detect characteristics of the sub-pixel SPX, including a threshold voltage of the first transistor T1, and the like, by using the sensing signal. Information on the characteristics of the sub-pixel SPX may be used to convert image data such that a characteristic deviation between sub-pixels SPX can be compensated. A second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to the control line CLi (for example, the ith control line). The first terminal of the third transistor T3 may be electrically connected to an initialization power source. The third transistor T3 is an initialization transistor capable of initializing the second node N2, and may be turned on in case that a sensing control signal is supplied from the control line CLi, to transfer a voltage of the initialization power source to the second node N2. Accordingly, a lower electrode LE (or first storage electrode) of the storage capacitor Cst, which is electrically connected to the second node N2, can be initialized.

The storage capacitor Cst may include the lower electrode LE (or first storage electrode) and an upper electrode UE (or second storage electrode). The lower electrode LE may be electrically connected to the second node N2, and the upper electrode UE may be electrically connected to the first node N1. The storage capacitor Cst may charge a data voltage corresponding to the data signal supplied to the first node N1 during a frame period. Accordingly, the storage capacitor Cst can store a voltage corresponding to a difference between a voltage of the gate electrode of the first transistor T1 and a voltage of the second node N2.

Although an embodiment in which the first to third transistors T1, T2, and T3 are all N-type transistors is disclosed in FIG. 5, the disclosure is not limited thereto. For example, at least one of the first to third transistors T1, T2, and T3 may be replaced with a P-type transistor. Also, although an embodiment in which the emission component EMU is electrically connected between the pixel circuit PXC and the second driving power source VSS is disclosed in FIG. 5, the emission component EMU may be electrically connected between the first driving power source VDD and the pixel circuit PXC.

The structure of the pixel circuit PXC may be variously modified and embodied. In an example, the pixel circuit PXC may further include at least one transistor element such as a transistor element for initializing the first node N1 and/or a transistor element for controlling an emission time of the light emitting elements LD, or other circuit elements such as a boosting capacitor for boosting a voltage of the first node N1.

In the following embodiments, for convenience of description, a lateral direction (or X-axis direction) in plan view may be represented as a first direction DR1, a longitudinal direction (or Y-axis direction) in plan view may be represented as a second direction DR2, and a longitudinal direction on a section may be represented as a third direction DR3.

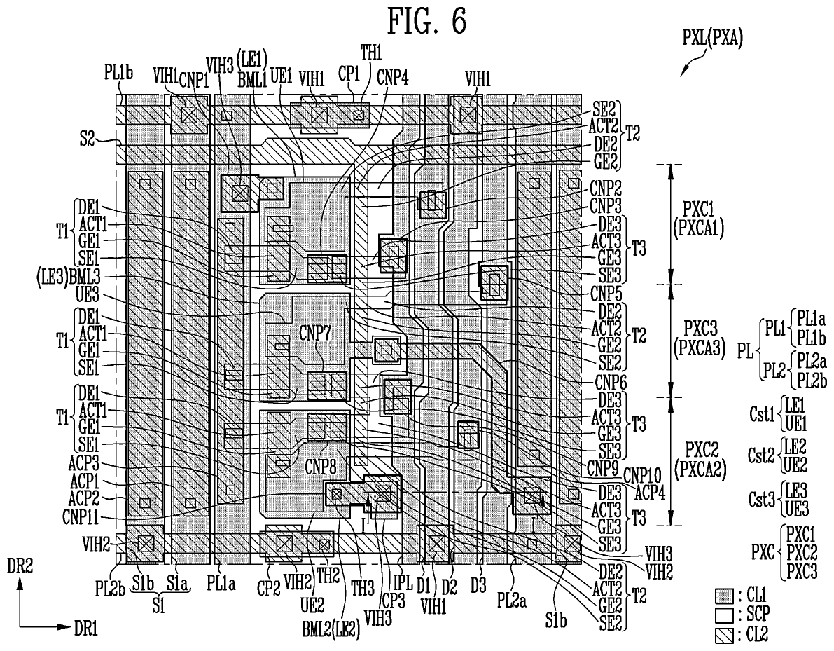

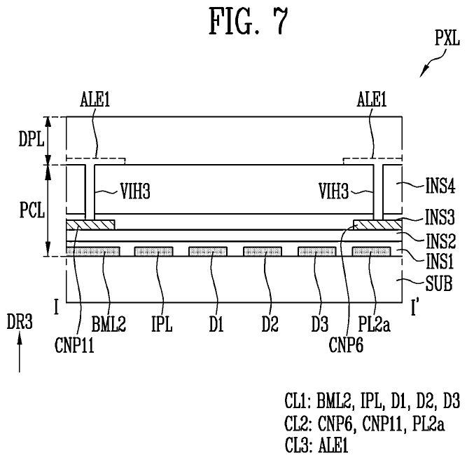

FIG. 6 is a schematic plan view illustrating a pixel circuit layer of a pixel PXL in accordance with an embodiment of the disclosure. FIG. 7 is a schematic cross-sectional view taken along line I-I′ shown in FIG. 6.

For example, FIGS. 6 and 7 schematically illustrate an embodiment of a structure of a pixel circuit layer PCL, based on a pixel area PXA in which the pixel PXL is disposed.

In FIGS. 6 and 7, the pixel PXL may include not only components included in the pixel PXL but also an area in which the components are provided (or located).

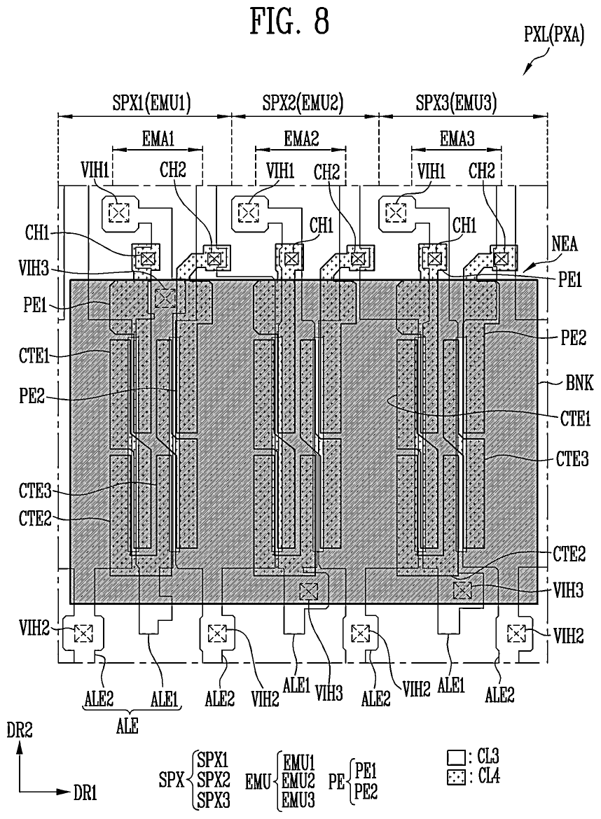

Referring to FIGS. 1 to 7, the pixel PXL may include a first sub-pixel SPX1, a second sub-pixel SPX2, and a third sub-pixel SPX3. The first sub-pixel SPX1 may include a first pixel circuit PXC1 and a first emission component (see “EMU1” shown in FIG. 8), the second sub-pixel SPX2 may include a second pixel circuit PXC2 and a second emission component (see “EMU2” shown in FIG. 8), and the third sub-pixel SPX3 may include a third pixel circuit PXC3 and a third emission component (see “EMU3” shown in FIG. 8).

The first pixel circuit PXC1, the second pixel circuit PXC2, and the third pixel circuit PXC3 may constitute a pixel circuit PXC of the pixel PXL. The first emission component EMU1, the second emission component EMU2, and the third emission component EMU3 may constitute an emission component EMU of the pixel PXL.

The pixel area PXA may include a first pixel circuit area PXCA1 in which the first pixel circuit PXC1 is provided, a second pixel circuit area PXCA2 in which the second pixel circuit PXC2 is provided, and a third pixel circuit area PXCA3 in which the third pixel circuit PXC3 is provided. Also, the pixel area PXA may include a first emission area (see “EMA1” shown in FIG. 8) in which light is emitted from light emitting elements LD driven by the first pixel circuit PXC1, a second emission area (see “EMA2” shown in FIG. 8) in which light is emitted from light emitting elements LD driven by the second pixel circuit PXC2, and a third emission area (see “EMA3” shown in FIG. 8) in which light is emitted from light emitting elements LD driven by the third pixel circuit PXC3. The first emission area EMA1 may be an emission area of the first sub-pixel SPX1, the second emission area EMA2 may be an emission area of the second sub-pixel SPX2, and the third emission area EMA3 may be an emission area of the third sub-pixel SPX3.

Hereinafter, in case that at least one sub-pixel among the first sub-pixel SPX1, the second sub-pixel SPX2, and the third sub-pixel SPX3 is arbitrarily designated or in case that two or more kinds of sub-pixels among the first sub-pixel SPX1, the second sub-pixel SPX2, and the third sub-pixel SPX3 are inclusively designated, the corresponding sub-pixel or the corresponding sub-pixels will be referred to as a “sub-pixel SPX” or “sub-pixels SPX.”

A pixel circuit layer PCL and a display element layer DPL may be disposed on a substrate SUB of the pixel PXL (or the pixel area PXA).

The pixel circuit layer PCL may include at least one insulating layer disposed on the substrate SUB. In an example, the pixel circuit layer PCL may include a first insulating layer INS1 (or buffer layer), a second insulating layer INS2 (or gate insulating layer), a third insulating layer INS3 (or passivation layer), and a fourth insulating layer INS4 (or via layer), which are sequentially stacked on each other on the substrate SUB along the third direction DR3.

The first insulating layer INS1 may be entirely disposed on the substrate SUB. The first insulating layer INS1 may prevent an impurity from being diffused into transistors T1, T2, and T3 included on the first to third pixel circuits PXC1, PXC2, and PXC3. The first insulating layer INS1 may be an inorganic insulating layer including an inorganic material. The first insulating layer INS1 may include at least one of silicon nitride (SiNₓ), silicon oxide (SiOₓ), and silicon oxynitride (SiOₓN_{y}), or include at least one of metal oxides such as aluminum oxide (AlOₓ). The first insulating layer INS1 may be provided as a single layer, but be provided as a multi-layer including at least two layers. In case that the first insulating layer INS1 is provided as the multi-layer, the layers may be formed of the same material or be formed of different materials. The first insulating layer INS1 may be omitted according to a material of the substrate SUB, a process condition, and the like.

The second insulating layer INS2 may be entirely disposed on the first insulating layer INS1. The second insulating layer INS2 may include the same material as the above-described first insulating layer INS1, or include an appropriate (or selected) material among the materials disclosed as the material constituting the first insulating layer INS1. In an example, the second insulating layer INS2 may be an inorganic insulating layer including an inorganic material.

The third insulating layer INS3 may be entirely provided and/or formed on the second insulating layer INS2. The third insulating layer INS3 may include the same material as the first insulating layer INS1, or include an appropriate (or selected) material among the materials disclosed as the material constituting the first insulating layer INS1.

The fourth insulating layer INS4 may be entirely provided and/or formed on the third insulating layer INS3. The fourth insulating layer INS4 may be an inorganic insulating layer including an inorganic material or an organic insulating layer including an organic material. The inorganic insulating layer may include, for example, at least one of silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin. In an embodiment, the fourth insulating layer INS4 may be an organic insulating layer.

The pixel circuit layer PCL may include at least one conductive layer disposed between the above-described insulating layers. In an example, the pixel circuit layer PCL may include a first conductive layer CL1 provided on the substrate SUB and a second conductive layer CL2 provided on the second insulating layer INS2.

Signal lines electrically connected to the pixel PXL may be formed on the substrate SUB. The signal lines may transfer a signal (or voltage) to the pixel PXL. In an example, the signal lines may include a first scan line S1, a second scan line S2, data lines D1, D2, and D3, a power line PL, and an initialization power line IPL.

A scan signal and a control signal may be selectively applied to the first scan line S1. The first scan line S1 may include a 1ath scan line S1a and a 1bth scan line S1b. The 1ath and 1bth scan lines S1a and S1b may extend along the second direction DR2. The 1ath and 1bth scan lines S1a and S1b may be configured with the first conductive layer CL1. The first conductive layer CL1 may be formed as a single layer or a multi-layer, which includes molybdenum (Mo), copper (Cu), aluminum (Al), chromium (Cr), gold (Au), titanium (Ti), nickel (Ni), neodymium (Nd), indium (In), tin (Sn), and oxides or alloys thereof.

The 1ath scan line S1a may be electrically connected to a first additional conductive pattern ACP1 through a contact hole penetrating the first and second insulating layers INS1 and INS2. The 1bth scan line S1b may be electrically connected to a second additional conductive pattern ACP2 through a contact hole penetrating the first and second insulating layers INS1 and INS2. Each of the first and second additional conductive patterns ACP1 and ACP2 may be configured with the second conductive layer CL2, and extend along the second direction DR2 and overlap the corresponding first scan line S1.

The 1ath scan line S1a may be electrically connected to the first additional conductive pattern ACP1 to be implemented in a double-layer structure. The 1bth scan line S1b may be electrically connected to the second additional conductive pattern ACP2 to be implemented in a double-layer structure. Accordingly, a line resistance of each of the 1ath and 1bth scan lines S1a and S1b may be reduced, so that signal distortion can be reduced.

A scan signal and a control signal may be selectively applied to the second scan line S2. The second scan line S2 may extend along the first direction DR1. The second scan line S2 may be configured with the second conductive layer CL2. The second conductive layer CL2 may include the same material as the first conductive layer CL1, or include an appropriate (or selected) material among the materials disclosed as the material constituting the first conductive layer CL1.

Although not directly shown in the drawings, the second scan line S2 may be electrically connected to the first scan line S1 through a contact hole.

In an embodiment, the second scan line S2 may be integrally provided with a second gate electrode GE2 of a second transistor T2 of each of the first, second, and third pixel circuits PXC1, PXC2, and PXC3. In an example, a portion of the second scan line S2 may be the second gate electrode GE2 of the second transistor T2 of each of the first, second, and third pixel circuits PXC1, PXC2, and PXC3. Accordingly, the second scan line S2 may be electrically connected to the second gate electrode GE2 of the second transistor T2 of each of the first, second, and third pixel circuits PXC1, PXC2, and PXC3.

Also, the second scan line S2 may be integrally provided with a third gate electrode GE3 of a third transistor T3 of each of the first, second, and third pixel circuits PXC1, PXC2, and PXC3. In an example, another portion of the second scan line S2 may be the third gate electrode GE3 of the third transistor T3 of each of the first, second, and third pixel circuits PXC1, PXC2, and PXC3. Accordingly, the second scan line S2 may be electrically connected to the third gate electrode GE3 of the third transistor T3 of each of the first, second, and third pixel circuits PXC1, PXC2, and PXC3.

The data lines D1, D2, and D3 may extend along the second direction DR2, and include a first data line D1, a second data line D2, and a third data line D3, which are spaced apart from each other in the first direction DR1. A data signal may be applied to each of the first, second, and third data lines D1, D2, and D3.

The first data line D1 may be electrically connected to a second transistor T2 of the first pixel circuit PXC1, the second data line may be electrically connected to a second transistor T2 of the second pixel circuit PXC2, and the third data line may be electrically connected to a second transistor T2 of the third pixel circuit PXC3.

The power line PL may include a first power line PL1 and a second power line PL2.

The first power line PL1 may include a first vertical power line PL1a extending in the second direction DR2 and a first horizontal power line PL1b extending in the first direction DR1. A voltage of the first driving power source VDD may be applied to the first power line PL1. The first vertical power line PL1a and the first horizontal power line PL1b may be disposed in different layers and be electrically connected to each other through a contact hole. For example, the first vertical power line PL1a may be configured with the first conductive layer CL1, and the first horizontal power line PL1b may be configured with the second conductive layer CL2. The first vertical power line PL1a and the first horizontal power line PL1b may be electrically connected to each other through a contact hole. The first power line PL1 may have a mesh structure due to the first vertical power line PL1a and the first horizontal power line PL1b, which are electrically connected to each other.

The first vertical power line PL1a may be electrically connected to a third additional conductive pattern ACP3 through a contact hole penetrating the first and second insulating layers INS1 and INS2. The third additional conductive pattern ACP3 may be configured with the second conductive layer CL2. The first vertical power line PL1a may be electrically connected to the third additional conductive pattern ACP3 to be implemented in a double-layer structure. Accordingly, a line resistance of the first vertical power line PL1a may be reduced, so that signal distortion can be reduced.

The second power line PL2 may include a second vertical power line PL2a extending in the second direction DR2 and a second horizontal power line PL2b extending in the first direction DR1. A voltage of the second driving power source VSS may be applied to the second power line PL2. The second vertical power line PL2a and the second horizontal power line PL2b may be disposed in different layers and be electrically connected to each other through a contact hole. For example, the second vertical power line PL2a may be configured with the second conductive layer CL2, and the second vertical power line PL2a and the second horizontal power line PL2b may be electrically connected to each other through a contact hole. The second power line PL2 may have a mesh structure due to the second vertical power line PL2a and the second horizontal power line PL2b, which are electrically connected to each other.

The second vertical power line PL2a may be electrically connected to a fourth additional conductive pattern ACP4 through a contact hole penetrating the first and second insulating layers INS1 and INS2. The fourth additional conductive pattern ACP4 may be configured with the second conductive layer CL2. The second vertical power line PL2a may be electrically connected to the fourth additional conductive pattern ACP4 to be implemented in a double-layer structure. Accordingly, a line resistance of the second vertical power line PL2a is reduced, so that signal distortion can be reduced.

The initialization power line IPL may extend in the second direction DR2. The initialization power line IPL may be the sensing line SENj (or the jth sensing line) described with reference to FIG. 5. The voltage of the initialization power source may be applied to the initialization power line IPL. In an embodiment, the initialization power line IPL may be configured with the first conductive layer CL1. The initialization power line IPL may be electrically connected to a third transistor T3 of the first pixel circuit PXC1 through a third connection pattern CNP3, and be electrically connected to a third transistor T3 of each of the second and third pixel circuits PXC2 and PXC3 through a ninth connection pattern CNP9.

The third connection pattern CNP3 may be configured with the second conductive layer CL2, and be disposed to overlap an area of the initialization power line IPL. The third connection pattern CNP3 may be electrically connected to the initialization power line IPL through a contact hole. Also, the third connection pattern CNP3 may be electrically connected to the third transistor T3 of the first pixel circuit PXC3 through a corresponding contact hole.

The ninth connection pattern CNP9 may be configured with the second conductive layer CL2, and be disposed to overlap another area of the initialization power line IPL. The ninth connection pattern CNP9 may be electrically connected to the initialization power line IPL through a contact hole. Also, the ninth connection pattern CNP9 may be electrically connected to the third transistor T3 of each of the second and third pixel circuits PXC2 and PXC3 through a corresponding contact hole.

The first power line PL1, the second power line PL2, the initialization power line IPL, the first scan line S1, and the second scan line S2, which are described above, may be common components commonly provided to the first, second, and third pixel circuits PXC1, PXC2, and PXC3.

The first pixel circuit PXC1 may include first, second, and third transistors T1, T2, and T3 and a first storage capacitor Cst1. The second pixel circuit PXC2 may include first, second, and third transistors T1, T2, and T3 and a second storage capacitor Cst2. The third pixel circuit PXC3 may include first, second, and third transistors T1, T2, and T3 and a third storage capacitor Cst3.

The first pixel circuit PXC1, the second pixel circuit PXC2, and the third pixel circuit PXC3 may have structures substantially similar or identical to one another. Hereinafter, the first pixel circuit PXC1 will be representatively described, and descriptions of the second and third pixel circuits PXC2 and PXC3 will be simplified.

The first pixel circuit PXC1 may include the first transistor T1, the second transistor T2, and the third transistor T3, and the first storage capacitor Cst1.

The first transistor T1 may include a first gate electrode GE1, a first active pattern ACT1, a first source electrode SE1, and a first drain electrode DE1.

The first gate electrode GE1 may be electrically connected to a second source electrode SE2 of the second transistor T2 through a contact hole. The first gate electrode GE1 may be configured with the second conductive layer CL2.

The first active pattern ACT1, the first source electrode SE1, and the first drain electrode DE1 may correspond to a semiconductor pattern made of poly-silicon, amorphous silicon, an oxide semiconductor, or the like. In an embodiment, the first active pattern ACT1, the first source electrode SE1, and the first drain electrode DE1 may correspond to a semiconductor layer SCP which is located between the first insulating layer INS1 and the second insulating layer INS2 and is made of an oxide semiconductor. The first active pattern ACT1, the first source electrode SE1, and the first drain electrode DE1 may be formed with a semiconductor layer undoped or doped with an impurity.

The first active pattern ACT1 is a region overlapping the first gate electrode GE1, and may be a channel region of the first transistor T1.

The first source electrode SE1 may be configured with an oxide semiconductor to have conductivity as an impurity is doped after the first gate electrode GE1 is formed. The first source electrode SE1 may be connected to the first active layer ACT1, and be electrically connected to a fourth connection pattern CNP4 through a contact hole.

The fourth connection pattern CNP4 may be configured with the second conductive layer CL2. The fourth connection pattern CNP4 may be electrically connected to the first source electrode SE1 through a contact hole penetrating the second insulating layer INS2, and be electrically connected to a third source electrode SE3 of the third transistor T3 through another contact hole penetrating the second insulating layer INS2. In an embodiment, the fourth connection electrode CNP4 may be electrically connected to a first lower metal pattern BML1 through a contact hole penetrating the first and second insulating layers INS1 and INS2.

The first lower metal pattern BML1 may be configured with the first conductive layer CL1. The first lower metal pattern BML1 may be electrically connected to the fourth connection pattern CNP4 through a contact hole. Also, the first lower metal pattern BML1 may be electrically connected to a first connection pattern CNP1 through a contact hole penetrating the first and second insulating layers INS1 and INS2.

The first connection pattern CNP1 may be configured with the second conductive layer CL2. The first connection pattern CNP1 may be electrically connected to the first lower metal pattern BML1 through a contact hole. Also, the first connection pattern CNP1 may be electrically connected to a partial configuration of the display element layer DPL through a corresponding third via hole VIH3 penetrating the third and fourth insulating layers INS3 and INS4.

The first drain electrode DE1 may be configured with an oxide semiconductor to have conductivity as an impurity is doped after the first gate electrode GE1 is formed. The first drain electrode DE1 may be connected to the first active pattern ACT1, and be electrically connected to the first vertical power line PL1a through a contact hole.

The second transistor T2 may include a second gate electrode GE2, a second active pattern ACT2, the second source electrode SE2, and a second drain electrode DE2.

The second gate electrode GE2 may be integrally provided with the second scan line S2.

The second active pattern ACT2, the second source electrode SE2, and the second drain electrode DE2 may correspond to a semiconductor layer SCP which is located between the first insulating layer INS1 and the second insulating layer INS2 and is made of an oxide semiconductor.

The second active pattern ACT2 is a region overlapping the second gate electrode GE2, and may be a channel region of the second transistor T2.

The second source electrode SE2 may be configured with an oxide semiconductor to have conductivity as an impurity is doped after the second gate electrode GE2. The second source electrode SE2 may be connected to the second active pattern ACT2, and be electrically connected to the first gate electrode GE1 of the first transistor T1 through a contact hole. In an embodiment, the second source electrode SE2 may be located on the first lower metal pattern BML1 with the first insulating layer INS1 interposed therebetween, thereby overlapping the first lower metal pattern BML1. The first lower metal pattern BML1 located on the bottom of the first insulating layer INS1 and the second source electrode SE2 located on the top of the first insulating layer INS1 with the first insulating layer interposed therebetween may constitute the first storage capacitor Cst1. In an example, the first lower metal pattern BML1 may be a first lower electrode LE1 of the first storage capacitor Cst1, and the second source electrode SE2 may be a first upper electrode UE1.

The second drain electrode DE2 may be configured with an oxide semiconductor to have conductivity as an impurity is doped after the second gate electrode GE2 is formed. The second drain electrode DE2 may be connected to the second active pattern ACT2, and be electrically connected to a second connection pattern CNP2 through a contact hole.

The second connection pattern CNP2 may be configured with the second conductive layer CL2. The second connection pattern CNP2 may be electrically connected to the second drain electrode DE2 through a contact hole. Also, the second connection pattern CNP2 may be electrically connected to the first data line D1 through a contact hole penetrating the first and second insulating layers INS1 and INS2. The second connection pattern CNP2 may electrically connect the second drain electrode DE2 and the first data line D1 to each other.

The third transistor T3 may include a third gate electrode GE3, a third active pattern ACT3, the third source electrode SE3, and a third drain electrode DE3.

The third gate electrode GE3 may be integrally provided with the second scan line S2.

The third active pattern ACT3, the third source electrode SE3, and the third drain electrode DE3 may correspond to a semiconductor layer SCP which is located between the first insulating layer INS1 and the second insulating layer INS2 and is made of an oxide semiconductor.

The third active pattern ACT3 is a region overlapping the third gate electrode GE3, and may be a channel region of the third transistor T3.

The third source electrode SE3 may be configured with an oxide semiconductor to have conductivity as an impurity is doped after the third gate electrode GE3 is formed. The third source electrode SE3 may be connected to the third active electrode ACT3, and be electrically connected to the fourth connection pattern CNP4 through a contact hole. The above-described third source electrode SE3 may be electrically connected to the first source electrode SE1 and the first lower metal pattern BML1 through the fourth connection pattern CNP4.

The third drain electrode DE3 may be configured with an oxide semiconductor to have conductivity as an impurity is doped after the third gate electrode GE3 is formed. The third drain electrode DE3 may be connected to the third active pattern ACT3, and be electrically connected to the third connection pattern CNP3 through a contact hole.

The third connection pattern CNP3 may be configured with the second conductive layer CL2. The third connection pattern CNP3 may be electrically connected to the third drain electrode DE3 through a contact hole. Also, the third connection pattern CNP3 may be electrically connected to the initialization power line IPL through a contact hole. The third connection pattern CNP3 may electrically connect the third drain electrode DE3 and the initialization power line IPL to each other.

The first storage capacitor Cst1 may include the first lower electrode LE1 and the first upper electrode UE1. The first storage capacitor Cst1 may be the storage capacitor Cst described with reference to FIG. 5. The first lower electrode LE1 may be integrally provided with the first lower metal pattern BML1. The first upper electrode UE1 may be integrally provided with the second source electrode SE2.

The second pixel circuit PXC2 may include the first transistor T1, the second transistor T2, the third transistor T3, and the second storage capacitor Cst2.

The first transistor T1 may include a first gate electrode GE1, a first active pattern ACT1, a first source electrode SE1, and a first drain electrode DE1.

The first gate electrode GE1 may be electrically connected to a second source electrode SE2 of the second transistor T2.

The first active pattern ACT1 may be a channel region of the first transistor T1.

The first source electrode SE1 may be connected to the first active pattern ACT1. The first source electrode SE1 may be electrically connected to an eighth connection pattern CNP8 through a contact hole.

The eighth connection pattern CNP8 may be configured with the second conductive layer CL2. The eighth connection pattern CNP8 may be electrically connected to the first source electrode SE1 through a contact hole penetrating the second insulating layer INS2, and be electrically connected to a third source electrode SE3 of the third transistor T3 through another contact hole penetrating the second insulating layer INS2. In an embodiment, the eighth connection pattern CNP8 may be electrically connected to a second lower metal pattern BML2 through a contact hole penetrating the first and second insulating layers INS1 and INS2.

The second lower metal pattern BML2 may be configured with the first conductive layer CL1. The second lower metal pattern BML2 may be electrically connected to the eighth connection pattern CNP8 through a contact hole. Also, the second lower metal pattern BML2 may be electrically connected to an eleventh connection pattern CNP11 through a contact hole penetrating the first and second insulating layers INS1 and INS2.

The eleventh connection pattern CNP11 may be configured with the second conductive layer CL2. The eleventh connection pattern CNP11 may be electrically connected to the second lower metal pattern BML2 through a contact hole. Also, the eleventh connection pattern CNP11 may be electrically connected to a partial configuration, for example, a first alignment electrode ALE1 of the display element layer DPL through a corresponding third via hole VIH3 penetrating the third and fourth insulating layers INS3 and INS4.

The first drain electrode DE1 may be connected to the first active pattern ACT1. The first drain electrode DE1 may be electrically connected to the first vertical power line PL1a through a contact hole.

The second transistor T2 may include a second gate electrode GE2, a second active pattern ACT2, the second source electrode SE2, and a second drain electrode DE2.

The second gate electrode GE2 may be integrally provided with the second scan line S2.

The second active pattern ACT2 may be a channel region of the second transistor T2.

The second source electrode SE2 may be connected to the second active pattern ACT2. The second source electrode SE2 may be electrically connected to the second gate electrode GE2 through a contact hole. In an embodiment, the second source electrode SE2 may be located on the second lower metal pattern BML2 with the first insulating layer INS1 interposed therebetween, thereby overlapping the second lower metal pattern BML2. The second lower metal pattern BML2 located on the bottom of the first insulating layer INS1 and the second source electrode SE2 located on the top of the first insulating layer INS1 with the first insulating layer INS1 interposed therebetween may constitute the second storage capacitor Cst2. In an example, the second lower metal pattern BML2 may be a second lower electrode LE2 of the second storage capacitor Cst2, and the second source electrode SE2 may be a second upper electrode UE2 of the second storage capacitor Cst2.

The second drain electrode DE2 may be connected to the second active pattern ACT2. The second drain electrode DE2 may be electrically connected to a tenth connection pattern CNP10 through a contact hole.

The tenth connection pattern CNP10 may be configured with the second conductive layer CL2. The tenth connection pattern CNP10 may be electrically connected to the second drain electrode DE2 through a contact hole. The tenth connection pattern CNP10 may be electrically connected to the second data line D2 through a contact hole penetrating the first and second insulating layers INS1 and INS2. The tenth connection pattern CNP10 may electrically connect the second drain electrode DE2 and the second data line D2 to each other.

The third transistor T3 may include a third gate electrode GE3, a third active pattern ACT3, the third source electrode SE3, and a third drain electrode DE3.

The third gate electrode GE3 may be integrally provided with the second scan line S2.

The third active pattern ACT3 is a region overlapping the third gate electrode GE3, and may be a channel region of the third transistor T3.

The third source electrode SE3 may be connected to the third active pattern ACT3, and be electrically connected to the eighth connection pattern CNP8 through a contact hole. The above-described third source electrode SE3 may be electrically connected to the first source electrode SE1 and the second lower metal pattern BML2 through the eighth connection pattern CNP8.

The third drain electrode DE3 may be connected to the third active pattern ACT3, and be electrically connected to the ninth connection pattern CNP9 through a contact hole. The ninth connection pattern CNP9 may electrically connect the third drain electrode DE3 and the initialization power line IPL to each other.

The second storage capacitor Cst2 may include the lower electrode LE2 and the second upper electrode UE. The second storage capacitor Cst2 may be the storage capacitor Cst described with reference to FIG. 5. The second lower electrode LE2 may be integrally provided with the second lower metal pattern BML2. The second upper electrode UE2 may be integrally provided with the second source electrode SE2.

The third pixel circuit PXC3 may include the first transistor T1, the second transistor T2, the third transistor T3, and the third storage capacitor Cst3.

The first transistor T1 may include a first gate electrode GE1, a first active pattern ACT1, a first source electrode SE1, and a first drain electrode DE1.

The first gate electrode GE1 may be electrically connected to a second source electrode SE2 of the second transistor T2.

The first active pattern ACT1 may be a channel region of the first transistor T1.

The first source electrode SE1 may be connected to the first active pattern ACT1. The first source electrode SE1 may be electrically connected to a seventh connection pattern CNP7 through a contact hole.

The seventh connection pattern CNP7 may be configured with the second conductive layer CL2. The seventh connection pattern CNP7 may be electrically connected to the first source electrode SE1 through a contact hole penetrating the second insulating layer INS2, and be electrically connected to a third source electrode SE3 of the third transistor T3 through another contact hole penetrating the second insulating layer INS2. In an embodiment, the seventh connection pattern CNP7 may be electrically connected to a third lower metal pattern BML3 through a contact hole penetrating the first and second insulating layers INS1 and INS2.

The third lower metal pattern BML3 may be configured with the first conductive layer CL1. The third lower metal pattern BML3 may be electrically connected to the seventh connection pattern CNP7 through a contact hole. Also, the third lower metal pattern BML3 may be electrically connected to a sixth connection pattern CNP6 through a contact hole penetrating the first and second insulating layers INS1 and INS2.

The sixth connection pattern CNP6 may be configured with the second conductive layer CL2. The sixth connection pattern CNP6 may be electrically connected to the third lower metal pattern BML3 through a contact hole. The sixth connection pattern CNP6 may be electrically connected to a partial configuration, for example, a first alignment electrode ALE1 of the display element layer DPL through a corresponding third via hole VIH3 penetrating the third and fourth insulating layers INS3 and INS4.

The first drain electrode DE1 may be connected to the first active pattern ACT1. The first drain electrode DE1 may be electrically connected to the first vertical power line PL1a through a contact hole.

The second transistor T2 may include a second gate electrode GE2, a second active pattern ACT2, the second source electrode SE2, and a second drain electrode DE2.

The second gate electrode GE2 may be integrally provided with the second scan line S2.

The second active pattern ACT2 may be a channel region of the second transistor T2.

The second source electrode SE2 may be connected to the second active pattern ACT2. The second source electrode SE2 may be electrically connected to the first gate electrode GE1 through a contact hole. In an embodiment, the second source electrode SE2 may be located on the third lower metal pattern BML3 with the first insulating layer INS1 interposed therebetween, thereby overlapping the third lower metal pattern BML3. The third lower metal pattern BML3 located on the bottom of the first insulating layer INS1 and the second source electrode SE2 located on the top of the first insulating layer INS1 with the first insulating layer INS1 interposed therebetween may constitute the third storage capacitor Cst3. In an example, the third lower metal pattern BML3 may be a third lower electrode LE3 of the third storage capacitor Cst3, and the second source electrode SE2 may be a third upper electrode UE3 of the third storage capacitor Cst3.

The second drain electrode DE2 may be connected to the second active pattern ACT2. The second drain electrode DE2 may be electrically connected to a fifth connection pattern CNP5 through a contact hole.

The fifth connection pattern CNP5 may be configured with the second conductive layer CL2. The fifth connection pattern CNP5 may be electrically connected to the second drain electrode DE2 through a contact hole. The fifth connection pattern CNP5 may be electrically connected to the third data line D3 through a contact hole penetrating the first and second insulating layers INS1 and INS2. The fifth connection pattern CNP5 may electrically connect the second drain electrode DE2 and the third data line D3 to each other.

The third transistor T3 may include a third gate electrode GE3, a third active pattern ACT3, the third source electrode SE3, and a third drain electrode DE3.

The third gate electrode GE3 may be integrally provided with the second scan line S2.

The third active pattern ACT3 is a region overlapping the third gate electrode GE3, and may be a channel region of the third transistor T3.

The third source electrode SE3 may be connected to the third active pattern ACT3, and be electrically connected to the seventh connection pattern CNP7 through a contact hole. The third source electrode SE3 may be electrically connected to the first source electrode SE1 and the third lower metal pattern BML3 through the seventh connection pattern CNP7.

The third drain electrode DE3 may be connected to the third active pattern ACT3, and be electrically connected to the ninth connection pattern CNP9 through a contact hole. The ninth connection pattern CNP9 may electrically connect the third drain electrode DE3 and the initialization power line IPL to each other.

The third storage capacitor Cst3 may include the third lower electrode LE3 and the third upper electrode UE3. The third storage capacitor Cst3 may be the storage capacitor Cst described with reference to FIG. 5. The third lower electrode LE3 may be integrally provided with the third lower metal pattern BML3. The third upper electrode UE3 may be integrally provided with the second source electrode SE2.

The above-described pixel PXL may include first, second, and third conductive patterns CP1, CP2, and CP3 disposed to be spaced apart from each other in the pixel area PXA.

The first conductive pattern CP1 may be configured with a first conductive layer CL1, may be located under an area of the first horizontal power line PL1b with the first and second insulating layers INS1 and INS2 interposed therebetween. The first horizontal power line PL1b and the first conductive pattern CP1 may overlap each other. The first conductive pattern CP1 may be a floating pattern to which any signal or voltage is not directly applied from the outside.

The second conductive pattern CP2 may be configured with the first conductive layer CL1, and be located under an area of the second horizontal power line PL2b with the first and second insulating layers INS1 and INS2 interposed therebetween. The second horizontal power line PL2b and the second conductive pattern CP2 may overlap each other. The second conductive pattern CP2 may be a floating pattern to which any signal or voltage is not directly applied from the outside.

The third conductive pattern CP3 may be configured with the first conductive layer CL1, and be located under the eleventh connection pattern CNP11 with the first and second insulating layers INS1 and INS2 interposed therebetween. The third conductive pattern CP3 and the eleventh connection pattern CNP11 may overlap each other. In an embodiment, the third conductive pattern CP3 may be integrally formed with the second lower metal pattern BML2 (or the second lower electrode LE2).

In an embodiment, the first and second insulating layers INS1 and INS2 may include a first through-hole TH1 exposing an area of the first conductive pattern CP1, a second through-hole TH2 exposing an area of the second conductive pattern CP2, and a third through-hole TH3 exposing an area of the third conductive pattern CP3.

The first horizontal power line PL1b may be electrically connected to the first conductive pattern CP1 while penetrating the first through-hole TH1, the second horizontal power line PL2b may be electrically connected to the second conductive pattern CP2 while penetrating the second through-hole TH2, and the eleventh connection pattern CNP11 may be electrically connected to the third conductive pattern CP3 while penetrating the third through-hole TH3.

Each of the first, second, and third pixel circuits PXC1, PXC2, and PXC3 may be covered by the third and fourth insulating layers INS3 and INS4.

In an embodiment, the third and fourth insulating layers INS3 and INS4 may be partially opened to include multiple via holes located in the pixel area PXA. The third and fourth insulating layers INS3 and INS4 may be partially opened to include three first via holes VIH1 exposing an area of the first horizontal power line PL1b and three second via holes VIH2 exposing an area of the second horizontal power line PL2b. Also, the third and fourth insulating layers INS3 and INS4 may be partially opened to include a third via hole VIH3 exposing each of the first connection pattern CNP1 of the first pixel circuit PXC1, the eleventh connection pattern CNP11 of the second pixel circuit PXC2, and the sixth connection pattern CNP6 of the third pixel circuit PXC3.

The first via hole VIH1 may electrically connect the first horizontal power line PL1b to a partial configuration of each of the first, second, and third emission components EMU1, EMU2, and EMU3.

The second via hole VIH2 may electrically connect the second horizontal power line PL2b to a partial configuration of each of the first, second, and third emission components EMU1, EMU2, and EMU3.

The third via hole VIH3 may electrically connect each of the first, sixth, and eleventh connection patterns CNP1, CNP6, and CNP11 to a partial configuration of each of the first, second, and third emission components EMU1, EMU2, and EMU3. In an example, the first connection pattern CNP1 may be electrically connected to a first alignment electrode (see “ALE1” shown in FIG. 8) of the first emission component EMU1 through a corresponding third via hole VIH3. The sixth connection pattern CNP6 may be electrically connected to a first alignment electrode of the third emission component EMU3 through a corresponding third via hole VIH3. The eleventh connection pattern CNP11 may be electrically connected to a first alignment electrode of the second emission component EMU2 through a corresponding third via hole VIH3.

An electrical connection relationship of the first, second, and third pixel circuits PXC1, PXC2, and PXC3 (or the pixel circuit layer PCL) and the first, second, and third emission components EMU1, EMU2, and EMU3 (or the display element layer DPL) will be described in detail later.

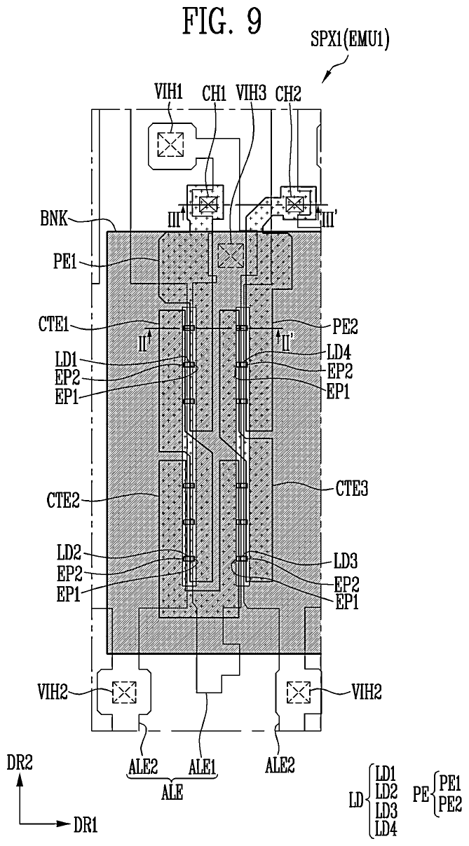

FIG. 8 is a schematic plan view illustrating a display element layer of a pixel PXL in accordance with an embodiment of the disclosure. FIG. 9 is a schematic plan view illustrating a first sub-pixel SPX1 shown in FIG. 8.

In the embodiment shown in FIG. 8, the display element layer of the pixel PXL may be located on the top of the pixel circuit layer of the pixel PXL shown in FIG. 6, thereby overlapping the pixel circuit layer.

Referring to FIGS. 1 to 9, the pixel PXL may include a light emission component EMU located in the display element layer DPL. The emission component EMU may include, for example, a first emission component EMU1, a second emission component EMU2, and a third emission component EMU3.

The first emission component EMU1 may include light emitting elements LD electrically connected to the first pixel circuit PXC and electrodes electrically connected to the light emitting elements LD, the second emission component EMU2 may include light emitting elements LD electrically connected to the second pixel circuit PXC2 and electrodes electrically connected to the light emitting elements LD, and the third emission component EMU3 may include light emitting elements LD electrically connected to the third pixel circuit PXC3 and electrodes electrically connected to the light emitting elements LD.

The display element layer DPL may include a bank BNK located in a non-emission area NEA.

The bank BNK may be a structure defining (or partitioning) first, second, and third emission areas EMA1, EMA2, and EMA3, and may be a pixel defining layer. For example, the bank BNK may be a structure defining an emission area of each of adjacent sub-pixels SPX. The bank BNK may define a supply position of light emitting elements LD in a process of supplying (or inputting) the light emitting elements LD to each sub-pixel SPX. For example, an emission area of each sub-pixel SPX may be partitioned (or defined) by the bank BNK, so that a mixed liquid (for example, ink) including a desired quantity and/or a desired kind of light emitting elements LD can be supplied (or input) to the corresponding emission area EMA.

In some embodiments, the bank BNK includes at least one light blocking material and/or at least one reflective material (or light scattering material), to prevent a light leakage defect in which light (or beam) is leaked between adjacent sub-pixels SPX. In some embodiments, the bank BNK may include a transparent material (or substance). The transparent material may include, for example, polyamide resin, polyimide resin, and/or the like, but the disclosure is not limited thereto. In another embodiment, a reflective material layer may be separately provided and/or formed on the bank BNK so as to further improve the efficiency of light emitted from each sub-pixel SPX.

The bank BNK may include opening areas exposing components located thereunder in a pixel area PXA. The light emitting elements LD of the first, second, and third emission components EMU1, EMU2, and EMU3 may be disposed in the opening areas.

In an embodiment, the bank BNK may be located on the top of a third via hole VIH3 in a non-emission area NEA of each sub-pixel SPX, thereby completely covering the third via hole VIH3. Accordingly, the third via hole VIH3 as a connection point of the pixel circuit layer PCL (or the pixel circuit PXC) and the display element layer DPL (or the emission component EMU) is covered by the bank BNK, not to be exposed to the outside. Thus, in case that light emitting elements LD are supplied and aligned in each of the first, second, and third emission areas EMA1, EMA2, and EMA3, the flow rate of the ink supplied to a corresponding emission area EMA in an area in which the third via hole VIH3 is located may not be increased, so that a failure in which the light emitting elements LD are aligned biased toward a specific area can be reduced.

The display element layer DPL may include an electrode PE (or pixel electrode) provided in each of the first, second, and third emission areas EMA1, EMA2, and EMA3, light emitting elements LD electrically connected to the electrode PE, and an alignment electrode ALE provided at a position corresponding to the electrode PE. In an example, a first electrode PE1 (or a first pixel electrode), a second electrode PE2 (or second pixel electrode), light emitting elements LD, and first and second alignment electrodes ALE1 and ALE2 may be disposed in each of the first, second, and third emission areas EMA1, EMA2, and EMA3. First, second, and third intermediate electrodes CTE1, CTE2, and CTE3 may be disposed in each of the first, second, and third emission areas EMA1, EMA2, and EMA3. The number, shape, size, arrangement structure, and the like of electrodes PE and/or alignment electrodes ALE may be variously modified according to the structure of first, second, and third sub-pixels SPX1, SPX2, and SPX3 (particularly, the first, second, and third emission components EMU1, EMU2, and EMU3).

In an embodiment, the alignment electrodes ALE, the light emitting elements LD, and the electrodes PE may be sequentially provided with respect to a surface of the substrate SUB, but the disclosure is not limited thereto.

The first emission component EMU1, the second emission component EMU2, and the third emission component EMU3 may have structures substantially similar or identical to one another. Hereinafter, components of the display element layer DPL will be described based on the first sub-pixel SPX1 having the first emission component EMU1.

The alignment electrode ALE may include a first alignment electrode ALE1 and a second alignment electrode ALE2, which are arranged to be spaced apart from each other in the first direction DR1. In an embodiment, the first alignment electrode ALE1 and the second alignment electrode ALE2 may extend in the second direction DR2. A second alignment electrode ALE2, a first alignment electrode ALE1, and a second alignment electrode ALE2 may be sequentially arranged along the first direction DR1 in at least each of the first, second, and third emission areas EMA1, EMA2, and EMA3. The first alignment electrode ALE1 and the second alignment electrode ALE2 may be provided in a bar shape which extends in the second direction DR2 and has at least one width in the first direction DR1, but the disclosure is not limited thereto.

The alignment electrode ALE may receive a predetermined or selected alignment signal before light emitting elements LD are aligned in each of the first, second, and third emission areas EMA1, EMA2, and EMA3 to be used as an electrode (or alignment line) for alignment of the light emitting elements LD. In an alignment process of light emitting elements LD, the first alignment electrode ALE1 may receive a first alignment signal, and the second alignment electrode ALE2 may receive a second alignment signal.

The above-described first and second alignment signals may be signals having a voltage difference and/or a phase difference to a degree to which the light emitting elements LD can be aligned between the first and second alignment electrodes ALE1 and ALE2. At least one of the first and second alignment signals may be an AC signal, but the disclosure is not limited thereto.

In an embodiment, the first alignment electrode ALE1 may be electrically connected to the first power line PL1 (for example, the first horizontal power line PL1b) through a first via hole VIH1, to receive the voltage of the first driving power source VDD from the first power line PL1 in a driving process of the light emitting elements LD. The second alignment electrode ALE2 may be electrically connected to the second power line PL2 (for example, the second horizontal power line PL2b) through a second via hole VIH2, to receive the voltage of the second driving power source VSS from the second power line PL2 in the driving process of the light emitting elements LD.

The first alignment electrode ALE1 may be separated from another electrode (for example, a first alignment electrode provided in an adjacent sub-pixel SPX in the second direction DR2) after light emitting elements LD are supplied and aligned in a manufacturing process of the display device DD. The second alignment electrode ALE1 may be commonly arranged in adjacent sub-pixels SPX in the second direction DR2. For example, the sub-pixels SPX may share the second alignment electrode ALE2. The above-described first and second alignment electrodes ALE1 and ALE2 may be configured with a third conductive layer CL3.

At least two to tens of light emitting elements LD may be aligned and/or disposed in the first emission area EMA1, but the number of the light emitting elements LD is not limited thereto. In some embodiments, the number of light emitting elements LD aligned and/or disposed in the first emission area EMA may be variously changed.

Each of the light emitting elements LD may be disposed between the first alignment electrode ALE1 and the second alignment electrode ALE2. In plan view, each of the light emitting elements LD may include a first end portion EP1 and a second end portion EP2, which are located at both ends (or face each other) in a length direction thereof, for example, the first direction DR1. In an embodiment, a second semiconductor layer (see “13” shown in FIG. 1) including a p-type semiconductor layer may be located at the first end portion EP1 (or p-type end portion), and a first semiconductor layer (see “11” shown in FIG. 1) including an n-type semiconductor layer may be located at the second end portion EP2 (or n-type end portion).

Each of the light emitting elements LD may emit any one of colored light and/or white light. Each of the light emitting elements LD may be aligned between the first alignment electrode ALE1 and the second alignment electrode ALE2 such that the length direction is parallel to the first direction DR1. The light emitting elements LD may be provided in a form in which the light emitting elements LD are dispersed in the ink, to be input (or supplied) to the first emission area EMA1. The light emitting elements LD may be input (or supplied) to the first emission area EMA1 through an inkjet printing process, a slit coating process, or other various processes.

In an embodiment, the light emitting elements LD may include a first light emitting element LD1, a second light emitting element LD2, a third light emitting element LD3, and a fourth light emitting element LD4.

The first light emitting element LD1 may be aligned between a left upper end area of a first alignment electrode ALE1 and a second alignment electrode ALE2 to be electrically connected to a first electrode PE1 and a first intermediate electrode CTE1. The first light emitting element LD1 may include a first end portion EP1 located adjacent to the first alignment electrode ALE1 and a second end portion EP2 located adjacent to the second alignment electrode ALE2. The first end portion EP1 of the first light emitting element LD1 may be electrically connected to the first electrode PE, and the second end portion EP2 of the first light emitting element LD1 may be electrically connected to the first intermediate electrode CTE1.

The second light emitting element LD2 may be aligned between a left lower end area of the first alignment electrode ALE1 and the second alignment electrode ALE2 to be electrically connected to the first alignment electrode CTE1 and a second intermediate electrode CTE2. The second light emitting element LD2 may include a first end portion EP1 located adjacent to the first alignment electrode ALE1 and a second end portion EP2 located adjacent to the second alignment electrode ALE2. The first end portion EP1 of the second light emitting element LD2 may be electrically connected to the first intermediate electrode CTE1, and the second end portion EP2 of the second light emitting element LD2 may be electrically connected to the second intermediate electrode CTE2.

The third light emitting element LD3 may be aligned between a right lower end area of the first alignment electrode ALE1 and a second alignment electrode ALE2 to be electrically connected to the second intermediate electrode CTE2 and a third intermediate electrode CTE3. The third light emitting element LD3 may include a first end portion EP1 located adjacent to the first alignment electrode ALE1 and a second end portion EP2 located adjacent to the second alignment electrode ALE2. The first end portion EP1 of the third light emitting element LD3 may be electrically connected to the second intermediate electrode CTE2, and the second end portion EP2 of the third light emitting element LD3 may be electrically connected to the third intermediate electrode CTE3.

The fourth light emitting element LD4 may be aligned between a right upper end area of the first alignment electrode ALE1 and the second alignment electrode ALE2 to be electrically connected to the third intermediate electrode CTE3 and a second electrode PE2. The fourth light emitting element LD4 may include a first end portion EP1 located adjacent to the first alignment electrode ALE1 and a second end portion EP2 located adjacent to the second alignment electrode ALE2. The first end portion EP1 of the fourth light emitting element LD4 may be electrically connected to the third intermediate electrode CTE3, and the second end portion EP2 of the fourth light emitting element LD4 may be electrically connected to the second electrode PE2.

As described above, the first end portion EP1 of each of the first, second, third, and fourth light emitting elements LD1, LD2, LD3, and LD4 may be located adjacent to a corresponding first alignment electrode ALE1, and the second end portion EP2 of each of the first, second, third, and fourth light emitting elements LD1, LD2, LD3, and LD4 may be located adjacent to a corresponding second alignment electrode ALE2.

Each of the first, second, third, and fourth light emitting elements LD1, LD2, LD3, and LD4 may be a light emitting diode having a subminiature size, for example, a size small to a degree of nanometer scale to micrometer scale, which is manufactured by using a material having an inorganic crystalline structure.

The first and second electrodes PE1 and PE2 and the first, second, and third intermediate electrodes CTE1, CTE2, and CTE3 may be provided in at least the first emission area EMA1, and each of the first and second electrodes PE1 and PE2 and the first, second, and third intermediate electrodes CTE1, CTE2, and CTE3 may be provided at a position corresponding to at least one alignment electrode ALE and light emitting elements LD. For example, each of the first and second electrodes PE1 and PE2 and the first, second, and third intermediate electrodes CTE1, CTE2, and CTE3 may be formed on alignment electrodes ALE and/or light emitting elements LD to overlap the alignment electrodes ALE and/or the light emitting elements LD. Therefore, each of the first and second electrodes PE1 and PE2 and the first, second, and third intermediate electrodes CTE1, CTE2, and CTE3 may be electrically connected to the light emitting elements LD.

The first electrode PE1 (or first pixel electrode) may be formed on a first area (for example, a left upper end area) of a first alignment electrode ALE1 and first end portions EP1 of first light emitting elements LD1, to be electrically connected to the first end portions EP1 of the first light emitting elements LD1. The first electrode PE1 may have a bar shape having a constant width along an extending direction thereof, for example, the second direction at least the first emission area EMA1, but the disclosure is not limited thereto. The first electrode PE1 may be configured with a fourth conductive layer CL4.

The first intermediate electrode CTE1 may be disposed on a first area (for example, an upper end area) of a second alignment electrode ALE2, which faces the first area of the first alignment electrode ALE1, and second end portions EP2 of the first light emitting elements LD1, to be electrically connected to the second end portions EP2 of the first light emitting elements LD1. Also, the first intermediate electrode CTE1 may be disposed on a second area (for example, a left lower end area) of the first alignment electrode ALE1 and first end portions EP1 of second light emitting elements LD2, to be electrically connected to the first end portions EP1 of the second light emitting elements LD2. For example, the first intermediate electrode CTE1 may be a bridge electrode which electrically connects the second end portions EP2 of the first light emitting elements LD1 to the first end portions EP1 of the second light emitting elements LD2 in the first emission area EMA1. To this end, the first intermediate electrode CTE1 may have a bent shape. For example, the first intermediate electrode CTE1 may have a bent or curved structure at a boundary between an area in which at least one first light emitting element LD1 is arranged and an area in which at least one second light emitting element LD2 is arranged. The first intermediate electrode CTE1 may be configured with the fourth conductive layer CL4.

The second intermediate electrode CTE2 may be disposed on a second area (for example, a lower end area) of the second alignment electrode ALE2 and second end portions EP2 of the second light emitting elements LD2, to be electrically connected to the second end portions EP2 of the second light emitting elements LD2. Also, the second intermediate electrode CTE2 may be disposed on a third area (for example, a right lower end area) of the first alignment electrode ALE1 and first end portions EP1 of third light emitting elements LD3, to be electrically connected to the first end portions EP1 of the third light emitting elements LD3. For example, the second intermediate electrode CTE2 may electrically connect the second end portions EP2 of the second light emitting elements LD2 to the first end portions EP1 of the third light emitting elements LD3 in the first emission area EMA1. To this end, the second intermediate electrode CTE2 may have a bent shape. For example, the second intermediate electrode CTE2 may have a bent or curved structure at a boundary between an area in which at least one second light emitting element LD2 is arranged and an area in which at least one third light emitting element LD3 is arranged. The second intermediate electrode CTE2 may be configured with the fourth conductive layer CL4.

The third intermediate electrode CTE3 may be disposed on a second area (for example, a lower end area) of a second alignment electrode ALE2, which faces the third area of the first alignment electrode ALE1, and second end portions EP2 of the third light emitting elements LD3, to be electrically connected to the second end portions EP2 of the third light emitting elements LD3. Also, the third intermediate electrode CTE3 may be disposed on a fourth area (for example, a right upper end area) of the first alignment electrode ALE1 and first end portions EP1 of fourth light emitting elements LD4, to be electrically connected to the first end portions EP1 of the fourth light emitting elements LD4. For example, the third intermediate electrode CTE3 may electrically connect the second end portions EP2 of the third light emitting elements LD3 to the first end portions EP1 of the fourth light emitting elements LD4 in the first emission area EMA1. To this end, the third intermediate electrode CTE3 may have a bent shape. For example, the third intermediate electrode CTE3 may have a bent or curved structure at a boundary between an area in which at least one third light emitting element LD3 is arranged and an area in which at least one fourth light emitting element LD4 is arranged. The third intermediate electrode CTE3 may be configured with the fourth conductive layer CL4.

The second electrode PE2 may be disposed on a first area (for example, an upper end area) of the second alignment electrode ALE2 and second end portions EP2 of the fourth light emitting elements LD4, to be electrically connected to the second end portions EP2 of the fourth light emitting elements LD. The second electrode PE2 may be configured with the fourth conductive layer CL4.

The first electrode PE1, the second electrode PE2, and the first, second, and third electrodes CTE1, CTE2, and CTE3 may be disposed to be spaced apart from each other in the first emission area EMA1.

In the above-described manner, the light emitting elements aligned between the alignment electrodes ALE may be electrically connected in a desired form by using the first and second electrodes PE1 and PE2 and the first, second, and third intermediate electrodes CTE1, CTE2, and CTE3. For example, the first light emitting elements LD1, the second light emitting elements LD2, the third light emitting elements LD3, and the fourth light emitting elements LD4 may be sequentially and electrically connected in series by using the first and second electrodes PE1 and PE2 and the first, second, and third intermediate electrodes CTE1, CTE2, and CTE3.

In an embodiment, the first electrode PE1 may be an anode of the first emission component EMU1, and the second electrode PE2 may be a cathode of the first emission component EMU1.

In each of the first, second, and third sub-pixels SPX1, SPX2, and SPX3, a first electrode PE1 may be electrically connected to a first alignment electrode ALE1 of a corresponding sub-pixel through a first contact hole CH1, and the first alignment electrode ALE1 may be electrically connected to a partial configuration of a pixel circuit PXC (or pixel circuit layer PCL) of the corresponding sub-pixel.

A first electrode PE1 of the first sub-pixel SPX1 may be electrically connected to a first alignment electrode ALE1 through a first contact hole CH1, the first alignment electrode ALE1 may be electrically connected to a first connection pattern CNP1 through a third via hole VIH3, and the first connection pattern CNP1 may be electrically connected to a first lower metal pattern BML1 through a contact hole. A first electrode PE1 of the second sub-pixel SPX1 may be electrically connected to a first alignment electrode ALE1 through a first contact hole CH1, the first alignment electrode ALE1 may be electrically connected to an eleventh connection pattern CNP11 through a third via hole VIH3, and the eleventh connection pattern CNP11 may be electrically connected to a second lower metal pattern BML2 through a contact hole. A first electrode PE1 of the third sub-pixel SPX3 may be electrically connected to a first alignment electrode ALE1 through a first contact hole CH1, the first alignment electrode ALE1 may be electrically connected to a sixth connection pattern CNP6 through a third via hole VIH3, and the sixth connection pattern CNP6 may be electrically connected to a third lower metal pattern BML3 through a contact hole.

In an embodiment, a second electrode PE2 of the first, second, and third sub-pixels SPX1, SPX2, and SPX3 may be electrically connected to a second alignment electrode ALE2 of a corresponding sub-pixel through a second contact hole CH2, and the second alignment electrode ALE2 may be electrically connected to a partial configuration of a corresponding pixel circuit PXC (or pixel circuit layer PCL) through a second via hole VIH2.

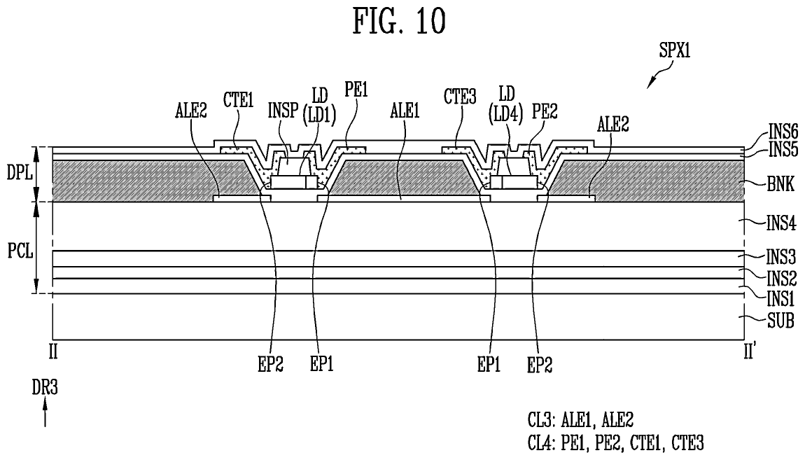

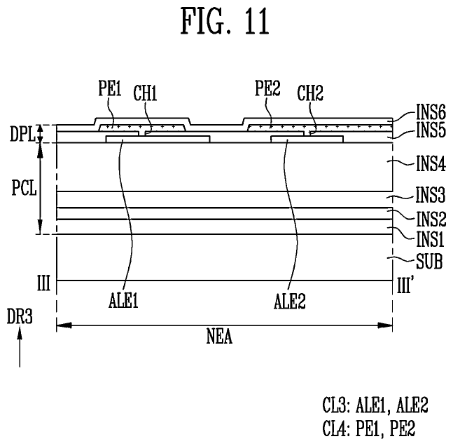

Hereinafter, a sectional structure (or stacked structure) of the first sub-pixel SPX1 will be described in detail with reference to FIGS. 10 and 11.

FIG. 10 is a schematic cross-sectional view taken along line II-II′ shown in FIG. 9. FIG. 11 is a schematic cross-sectional view taken along line III-III′ shown in FIG. 9.

In FIGS. 10 and 11, the firs sub-pixel SPX1 is simplified and illustrated, such as that each electrode is illustrated as an electrode having a signal layer and each insulating layer is illustrated as an insulating layer provided as a single layer, but the disclosure is not limited thereto.

In relation to the embodiment shown in FIGS. 10 and 11, portions different from the portions of the above-described embodiment will be described to avoid redundancy.

Referring to FIGS. 1 to 11, the first sub-pixel SPX1 may include a substrate SUB, a pixel circuit layer PCL, and a display element layer DPL.

The pixel circuit layer PCL and the display element layer DPL may be disposed on a surface of the substrate SUB to overlap each other. In an example, the pixel area PXA of the substrate SUB may include the pixel circuit layer PCL disposed on the surface of the substrate SUB and the display element layer DPL disposed on the pixel circuit layer PCL. The pixel circuit layer PCL may include a first insulating layer INS1, a second insulating layer INS2, a third insulating layer INS3, and a fourth insulating layer INS4, which are sequentially stacked on each other on the substrate SUB.

The display element layer DPL may include first and second alignment electrodes ALE1 and ALE2, a bank BNK, light emitting elements LD, electrodes PE, and first, second, and third intermediate electrodes CTE1, CTE2, and CTE3. In an embodiment, in the display element layer DPL, the alignment electrodes ALE, the bank BNK, the light emitting elements LD, the electrodes PE, and/or the intermediate electrodes CTE1, CTE2, and CTE3 may be sequentially provided with respect to a surface of the pixel circuit layer PCL (or the fourth insulating layer INS4) so as to discharge an outgas generated from an organic layer included in the pixel circuit layer PCL.

The first alignment electrode ALE1 and the second alignment electrode ALE2 may be provided and/or formed on the pixel circuit layer PCL (or the fourth insulating layer INS4). The first and second alignment electrodes ALE1 and ALE2 may correspond to a third conductive layer CL3 disposed on the fourth insulating layer INS4.

The first alignment electrode ALE1 and the second alignment electrode ALE2 may be disposed on the same plane, and have the same thickness in the third direction DR3. The first alignment electrode ALE1 and the second alignment electrode ALE2 may be simultaneously or continuously formed through the same process.

The first alignment electrode ALE1 and the second alignment electrode ALE2 may be configured with a material having reflexibility to allow light emitted from the light emitting elements LD to advance in an image display direction (or front direction) of the display device DD. In an example, the alignment electrodes ALE may be made of a conductive material (or substance). In case that the first alignment electrode ALE1 and the second alignment electrode ALE2 is configured with a conductive material having reflexibility, light emitted from both end portions EP1 and EP2 of each of the light emitting elements LD may further advance in the image display direction of the display device DD.

At least one first alignment electrode ALE1 and at least one second alignment electrode ALE2 may be disposed in the first emission area EMA1. For example, one first alignment electrode ALE1 may be disposed at the center of the first emission area EMA1, and two second alignment electrodes ALE2 may be disposed to be spaced apart from each other with the first alignment electrode ALE1 interposed therebetween. The two second alignment electrodes ALE2 may be integrally or non-integrally connected to each other to be supplied with the same signal and the same power source. Each of the two second alignment electrodes ALE2 may be integrally formed with a second alignment electrode ALE2 of an adjacent sub-pixel to be electrically connected to each other. In an example, one second alignment electrode ALE2 located at a right side of the one first alignment electrode ALE1 among the two second alignment electrodes ALE2 may be integrally formed with one second alignment electrode ALE2 of the second sub-pixel SPX2 adjacent to the first sub-pixel SPX1 to be electrically connected to each other.

The number, shape, size, and/or positions of each of first and second alignment electrodes ALE1 and ALE2 disposed in the first emission area EMA1 may be variously changed in some embodiments.

The bank BNK may be located on the first and second alignment electrodes ALE1 and ALE2 in at least the first emission area EMA1, thereby covering the first alignment electrode ALE1 and the second alignment electrode ALE2. The bank BNK may be partially opened to respectively expose portions of the first alignment electrode ALE1 and the second alignment electrode ALE2, which are located in an area in which the light emitting elements LD are aligned. In an example, the bank BNK may have openings or concave parts, corresponding to areas between the first and second alignment electrodes ALE1 and ALE2 in the first emission area EMA1, and be formed in an integrated pattern entirely connected in the pixel area PXA.

In an embodiment, the bank BNK may be a structure accurately defining alignment positions of the light emitting elements LD, and, simultaneously, be a pixel defining layer located even in the non-emission area NEA, thereby defining the first emission area EMA1 of the first sub-pixel SPX1.

A fifth insulating layer INS5 may be disposed over the first and second alignment electrodes ALE1 and ALE2 and the bank BNK.

The fifth insulating layer INS5 may be entirely provided and/or formed on the pixel circuit layer PCL. The fifth insulating layer INS5 may be configured as a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and/or titanium oxide (TiOₓ).

The fifth insulating layer INS5 may be partially opened in at least the non-emission area NEA. In an example, the fifth insulating layer INS5 may be partially opened to include a first contact hole CH1 exposing an area of the first alignment electrode ALE1 and a second contact hole CH2 exposing an area of the second alignment electrode ALE2 in at least the non-emission area NEA.

The light emitting elements LD may be disposed on the fifth insulating layer INS5. The light emitting elements LD may be disposed between the alignment electrodes ALE on the fifth insulating layer INS5.

In an example, the light emitting elements LD may be supplied (or input) to the first emission area EMA1 through an inkjet printing process or the like, and each of the light emitting elements LD may be aligned on a surface of the fifth insulating layer INS5, which is located in an area between the first alignment electrode ALE1 and the second alignment electrode ALE2, by an electric field formed by a signal (or alignment signal) applied to each of the first alignment electrode ALE1 and the second alignment electrode ALE2. For example, the light emitting elements LD supplied to the first emission area EMA1 may be arranged such that first end portions EP1 face the first alignment electrode ALE1 and second end portions EP2 face the second alignment electrode ALE2.

The light emitting elements LD may include a first light emitting element LD1, a second light emitting element LD2, a third light emitting element LD3, and a fourth light emitting element LD4.

An insulating pattern INSP may be disposed on each of the first, second, third, and fourth light emitting elements LD1, LD2, LD3, and LD4. The insulating pattern INSP may be located on each of the first, second, third, and fourth light emitting elements LD1, LD2, LD3, and LD4 and partially cover an outer circumferential surface (or surface) of each of the first, second, third, and fourth light emitting elements LD1, LD2, LD3, and LD4, thereby exposing, to the outside, a first end portion EP1 and a second end portion EP2 of each of the first, second, third, and fourth light emitting elements LD1, LD2, LD3, and LD4.

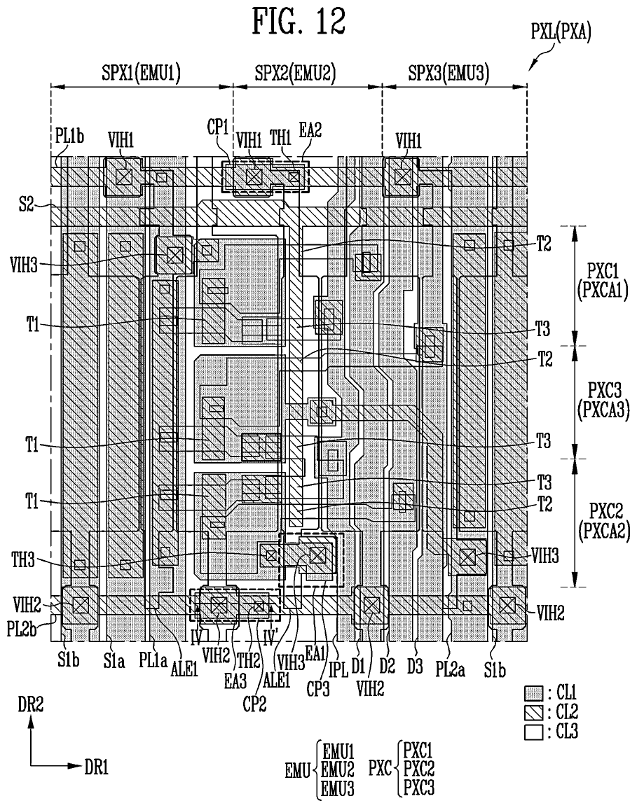

The insulating pattern INSP may include an inorganic insulating layer including an inorganic material or an organic insulating layer. In an example, the insulating pattern INSP may include an inorganic insulating layer suitable for protecting an active layer (see “12” shown in FIG. 12) of each of the first, second, third, and fourth light emitting elements LD1, LD2, LD3, and LD4 from external oxygen, moisture, and the like. However, the disclosure is not limited thereto, and the insulating pattern INSP may be configured as an organic insulating layer including an organic material according to a design condition and the like of the display device DD (or the display panel DP) to which the first, second, third, and fourth light emitting elements LD1, LD2, LD3, and LD4 are applied. The insulating pattern INSP may be configured as a single layer or a multi-layer.

In case that an empty gap (or space) exists between the fifth insulating layer INS5 and the light emitting elements LD before the insulating pattern INSP is formed, the empty gap may be filled with the insulating pattern INSP in a process of forming the insulating pattern INSP. The insulating pattern INSP is formed on each of the first, second, third, and fourth light emitting elements LD1, LD2, LD3, and LD4 which are completely aligned in the first emission area EMA, so that the first, second, third, and fourth light emitting elements LD1, LD2, LD3, and LD4 can be prevented from being separated positions at which the first, second, third, and fourth light emitting elements LD1, LD2, LD3, and LD4 are aligned.

First and second electrode PE1 and PE2 and first, second, and third intermediate electrodes CTE1, CTE2, and CTE3 may be formed on both end portions, for example, first and second end portions EP1 and EP2 of each of the light emitting elements LD, which are not covered by the insulating pattern INSP.

The first electrode PE1 may be directly disposed on first end portions EP1 of first light emitting elements LD1, to be in contact with the first end portions EP1 of the first light emitting elements LD1.

The first intermediate electrode CTE1 may be directly disposed on second end portions EP2 of the first light emitting elements LD1, to be in contact with the second end portions EP2 of the first light emitting elements LD1. Also, the first intermediate electrode CTE1 may be directly disposed on first end portions EP1 of second light emitting elements LD2, to be in contact with the first end portions EP1 of the second light emitting elements LD2. For example, the first intermediate electrode CTE1 may electrically connect the second end portions EP2 of the first light emitting elements LD1 to the first end portions EP1 of the second light emitting elements LD2.

The second intermediate electrode CTE2 may be directly disposed on second end portions EP2 of the second light emitting elements LD2, to be in contact with the second end portions EP2 of the second light emitting elements LD2. Also, the second intermediate electrode CTE2 may be directly disposed on first end portions EP1 of third light emitting elements LD3, to be in contact with the first end portions EP1 of the third light emitting elements LD3. For example, the second intermediate electrode CTE2 may electrically connect the second end portions EP2 of the second light emitting elements LD2 to the first end portions EP1 of the third light emitting elements LD3.

The third intermediate electrode CTE3 may be directly disposed on second end portions EP2 of the third light emitting elements LD3, to be in contact with the second end portions EP2 of the third light emitting elements LD3. Also the third intermediate electrode CTE3 may be directly disposed on first end portions EP1 of fourth light emitting elements LD4, to be in contact with the first end portions EP1 of the fourth light emitting elements LD4. For example, the third intermediate electrode CTE3 may electrically connect the second end portions EP2 of the third light emitting elements LD3 to the first end portions EP1 of the fourth light emitting elements LD4.

The second electrode PE2 may be directly disposed on second end portions EP2 of the fourth light emitting elements LD4, to be in contact with the second end portions EP2 of the fourth light emitting elements LD4, thereby being electrically connected to the second end portions EP2 of the fourth light emitting elements LD4.

The first and second electrodes PE1 and PE2 and the first, second, and third intermediate electrodes CTE1, CTE2, and CTE3 may be configured with a fourth conductive layer CL4 disposed on the insulating pattern INSP. The first and second electrodes PE1 and PE2 and the first, second, and third intermediate electrodes CTE1, CTE2, and CTE3 may be simultaneously formed through the same process.

Each of the first and second electrodes PE1 and PE2 and the first, second, and third intermediate electrodes CTE1, CTE2, and CTE3 may be configured with various transparent conductive materials.

A sixth insulating layer INS6 may be disposed over the first and second electrodes PE1 and PE2 and the first, second, and third intermediate electrodes CTE1, CTE2, and CTE3. The sixth insulating layer INS6 may be located over the first and second electrodes PE1 and PE2 and the first, second, and third intermediate electrodes CTE1, CTE2, and CTE3, thereby covering the first and second electrodes PE1 and PE2 and the first, second, and third intermediate electrodes CTE1, CTE2, and CTE3. The sixth insulating layer INS6 may include an inorganic insulating layer made of an inorganic material or an organic insulating layer made of an organic material.

As described above, the first and second electrodes PE1 and PE2 and the first, second, and third intermediate electrodes CTE1, CTE2, and CTE3 may be disposed in the same layer as the display element layer DPL, and be simultaneously or continuously formed. Thus, In case that electrodes disposed on the first end portion EP1 and the second end portion EP2 of each light emitting element LD are disposed in the same layer and are simultaneously formed, a manufacturing process of the pixel PXL (or the display device DD) can be simplified, and process efficiency can be improved.

In some embodiments, at least one overcoat layer (for example, a layer which planarizes a top surface of the display element layer DPL) may be further disposed on the top of the first and second electrodes PE1 and PE2 and the first, second, and third intermediate electrodes CTE1, CTE2, and CTE3.

In other embodiments, an optical layer (see “LCL” shown in FIG. 4) may be selectively disposed on the top of the display element layer DPL of each sub-pixel SPX. In an example, the optical layer LCL may include a color conversion layer including color conversion particles for converting light emitted from light emitting elements LD into light of a specific color.

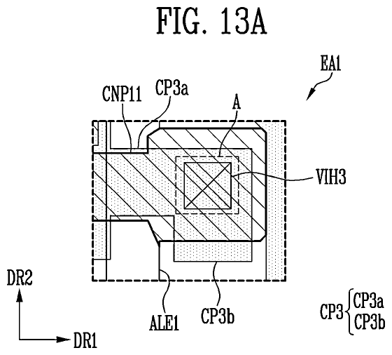

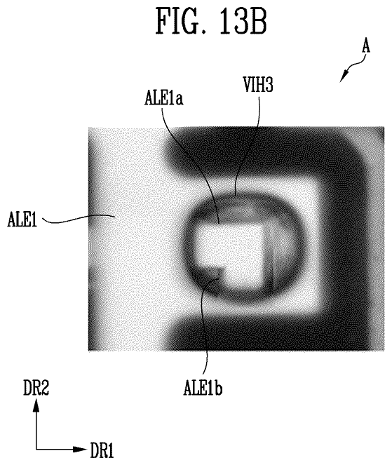

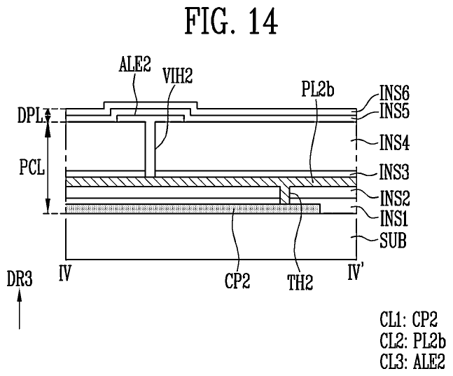

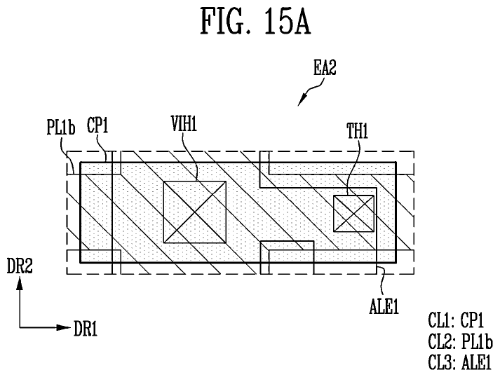

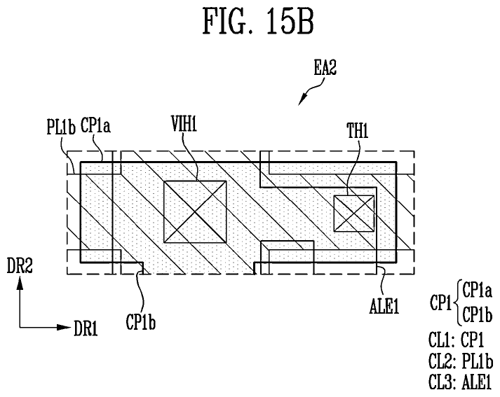

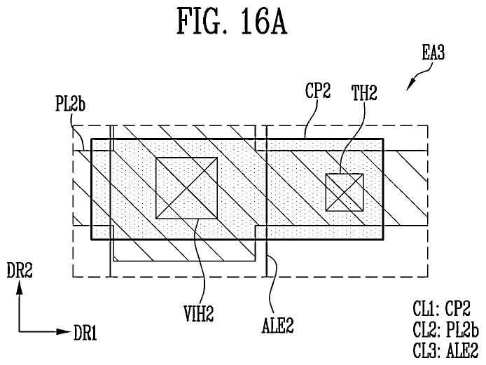

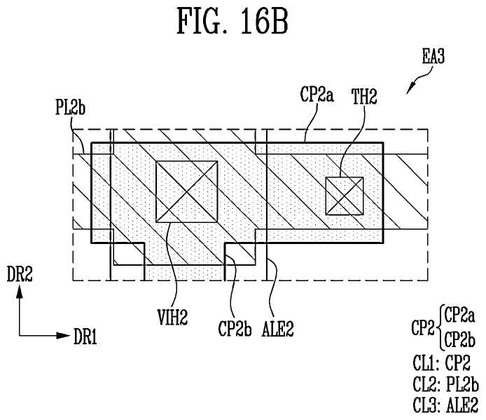

FIG. 12 is a schematic plan view illustrating a pixel PXL in which an alignment electrode ALE is included in the pixel shown in FIG. 6. FIG. 13A is a schematic enlarged view illustrating portion EA1 shown in FIG. 12. FIG. 13b is a schematic image obtained by enlarging area A shown in FIG. 13A, using an electron microscope. FIG. 14 is a schematic cross-sectional view taken along line IV-IV′ shown in FIG. 12. FIGS. 15A and 15B are schematic enlarged views illustrating portion EA2 shown in FIG. 12. FIGS. 16A and 16B are schematic enlarged views illustrating portion EA3 shown in FIG. 12.

In FIGS. 12 to 16B, portions different from the portions of the above-described embodiment will be described to avoid redundancy. Portions not particularly described in the embodiment shown in FIGS. 12 to 16B follow those of the above-described embodiments. Identical reference numerals refer to identical components, and similar reference numerals refer to similar components.

Referring to FIGS. 1 to 16B, the pixel PXL in accordance with an embodiment of the disclosure may include a first conductive layer CL1, a second conductive layer CL2, and a third conductive layer CL3, which are sequentially formed on a surface of a substrate SUB.

The first conductive layer CL1 may include first and second vertical power lines PL1a and PL2a, an initialization line IPL, data lines D1, D2, and D3, 1ath and 1bth scan lines S1a and S1b, first, second, and third lower metal patterns BML1, BML2, and BML3, first, second, and third conductive patterns CP1, CP2, and CP3, and the like, which are disposed to be spaced apart from each other on the substrate SUB.

The second conductive layer CL2 may include first to eleventh connection patterns CNP1 to CNP11, first to fourth additional conductive patterns ACP1 to ACP4, first and second horizontal lines PL1b and PL2b, a second scan line S2, and first gate electrodes GE1, which are disposed to be spaced apart from each other on a second insulating layer INS2.

The third conductive layer CL3 may include first alignment electrodes ALE1 and second alignment electrodes ALE2, which are disposed to be spaced apart from each other on a fourth insulating layer INS4.

In an embodiment, the first, second, and third conductive layers CL1, CL2, and CL3 may be located while overlapping each other in the vicinity of first, second, and third via holes VIH1, VIH2, and VIH3 corresponding to electrical connection points of a pixel circuit PXC and an emission component EMU

In a first sub-pixel SPX1, a first via hole VIH1, and a 1ath scan line S1a (for example, a first component) configured with the first conductive layer CL1, a first horizontal power line PL1b (for example, a second component) configured with the second conductive layer CL2, and a first alignment electrode ALE1 (for example, a third component) configured with the third conductive layer CL3 in the vicinity of the first via hole VIH1 may be located while overlapping each other.

In the first sub-pixel SPX1, a second via hole VIH2, and a 1bth scan line S1b (for example, a first component) configured with the first conductive layer CL1, a second horizontal power line PL2b (for example, a second component) configured with the second conductive layer CL2, and a second alignment electrode ALE2 (for example, a third component) configured with the third conductive layer CL3 in the vicinity of the second via hole VIH2 may be located while overlapping each other. In the first sub-pixel SPX1, another second via hole VIH2, and a second conductive pattern CP2 (for example, a first component) configured with the first conductive layer CL1, the second horizontal power line PL2b (for example, a second component) configured with the second conductive layer CL2, and another second alignment electrode ALE2 (for example, a third component) configured with the third conductive layer CL3 in the vicinity of the another second via hole VIH2 may be located while overlapping each other.

In the first sub-pixel SPX1, a third via hole VIH3, and a first vertical power line PL1a (for example, a first component) configured with the first conductive layer CL1, a first connection pattern CNP1 (for example, a second component) configured with the second conductive layer CL2, and a first alignment electrode ALE1 (for example, a third component) configured with the third conductive layer CL3 in the vicinity of the third via hole VIH3 may be located while overlapping each other.

In a second sub-pixel SPX2, a first via hole VIH1, and a first conductive pattern CP1 (for example, a first component) configured with the first conductive layer CL1, a first horizontal power line PL1b (for example, a second component) configured with the second conductive layer CL2, and a first alignment electrode ALE1 (for example, a third component) configured with the third conductive layer CL3 in the vicinity of the first via hole VIH1 may be located while overlapping each other.

In the second sub-pixel SPX2, a second via hole VIH2, and a first data line D1 (for example, a first component) configured with the first conductive layer CL1, a second horizontal power line PL2b (for example, a second component) configured with the second conductive layer CL2, and a second alignment electrode ALE2 (for example, a third component) configured with the third conductive layer CL3 in the vicinity of the second via hole VIH2 may be located while overlapping each other.

In the second sub-pixel SPX2, a third via hole VIH3, and a third conductive pattern CP3 (or second lower metal pattern BML2) (for example, a first component) configured with the first conductive layer CL1, an eleventh connection pattern CNP11 (for example, a second component) configured with the second conductive layer CL2, and a first alignment electrode ALE1 (for example, a third component) configured with the third conductive layer CL3 in the vicinity of the third via hole VIH3 may be located while overlapping each other.

In a third sub-pixel SPX3, a first via hole VIH1, and a second data line D2 (for example, a first component) configured with the first conductive layer CL1, a horizontal power line PL1b (for example, a second component) configured with the second conductive layer CL2, and a first alignment electrode ALE1 (for example, a third component) configured with the third conductive layer CL3 in the vicinity of the first via hole VIH1 may be located while overlapping each other.

In the third sub-pixel SPX3, a second via hole VIH2, and a 1bth scan line S1b (for example, a first component) configured with the first conductive layer CL1, a second horizontal power line PL2b (for example, a second component) configured with the second conductive layer CL2, and a second alignment electrode ALE2 (for example, a third component) configured with the third conductive layer CL3 in the vicinity of the second via hole VIH2 may be located while overlapping each other.

In the third sub-pixel SPX3, a third via hole VIH3, and a second vertical power line PL2a (for example, a first component) configured with the first conductive layer CL1, a sixth connection pattern CNP6 (for example, a second component) configured with the second conductive layer CL2, and a first alignment electrode ALE1 (for example, a third component) configured with the third conductive layer CL3 in the vicinity of the third via hole VIH3 may be located while overlapping each other.

In the second sub-pixel SPX2, the first alignment electrode ALE1 may be electrically connected to the eleventh connection pattern CNP11 while penetrating the third via hole VIH3 of third and fourth insulating layers INS3 and INS4, and the eleventh connection pattern CNP11 may be electrically connected to the third conductive pattern CP3 while penetrating a third through-hole TH3 of first and second insulating layers INS1 and INS2.

In an embodiment, the third conductive pattern CP3 may be a component added to reduce a contact failure of the third via hole VIH3, and the eleventh connection pattern CNP11 configured with the second conductive layer CL2 and the first alignment electrode ALE1 configured with the third conductive layer CL3 in the vicinity of the third via hole VIH3. In an example, the third conductive pattern CP3 may be used as a step difference compensation pattern for reducing a step difference occurring due to the third via hole VIH3 and components located on the bottom of the first alignment electrode ALE1 in the vicinity of the third via hole VIH3. As the third conductive pattern CP3 is disposed, the third via hole VIH3 and components, for example, the third conductive pattern CP3, the first and second insulating layers INS1 and INS2, the eleventh connection pattern CNP11, and the third and fourth insulating layers INS3 and INS4, which are stacked on each other in the vicinity of the third via hole VIH3, may have a gentle step coverage, so that the first alignment electrode ALE1 located on the top of the third via hole VIH3 and the eleventh connection pattern CNP11 exposed by the third via hole VIH3 can be more stably electrically connected to each other.

The above-described third conductive pattern CP3 may have a “¬” shape including a first part CP3a extending in the first direction DR1 from the second lower metal pattern BML2 (or a first lower electrode LE1) and a second part CP3b extending in the second direction DR2 different from (or intersecting) the first direction DR1, but the disclosure is not limited thereto. The above-described third conductive pattern CP3 may be designed in various shapes so as to allow the first alignment electrode ALE1 located on the top thereof to have at least two current paths. The first alignment electrode ALE1 located on the top of the third via hole VIH3 may have a shape corresponding to the shape of the third conductive pattern CP3 in the third via hole VIH3. In an example, as shown in FIG. 13B, the first alignment electrode ALE1 may have a “¬” shape including a first extension part ALE1a extending in the first direction DR1 in the third via hole VIH3 and a second extension part ALE1b extending in the second direction DR2 different from (or intersecting) the first direction DR1. The first alignment electrode ALE1 having the “¬” shape in the third via hole

VIH3 may form at least two current paths. For example, the first alignment electrode ALE1 may form a first current path through which a current flows toward the first extension part ALE1a in the third via hole VIH3 and a second path through which a current flows toward the second extension part ALE1b. Accordingly, the contact failure of the first alignment electrode ALE1 and the eleventh connection pattern CNP11, which are electrically connected to each other while penetrating the third via hole VIH3, can be reduced.

In the second sub-pixel SPX2, the first alignment electrode ALE1 may be electrically connected to the first horizontal power line PL1b while penetrating the first via hole VIH1 of the third and fourth insulating layers INS3 and INS4, and the first horizontal power line PL1b may be electrically connected to the first conductive pattern CP1 while penetrating a first through-hole TH1 of the first and second insulating layers INS1 and INS2.

In an embodiment, the first conductive pattern CP1 may be a component added to reduce a contact failure of the first via hole VIH1, and the first horizontal power line PL1b configured with the second conductive layer CL2 and the first alignment electrode ALE1 configured with the third conductive layer CL3in the vicinity of the first via hole VIH1. In an example, the first conductive pattern CP1 may be used as a step difference compensation pattern for reducing a step difference occurring due to the first via hole VIH1 and components located on the bottom of the first alignment electrode ALE1 in the vicinity of the first via hole VIH1. As the first conductive pattern CP1 is disposed, the first via hole VIH1 and components, for example, the first conductive pattern CP1, the first and second insulating layers INS1 and INS2, the first horizontal power line PL1b, and the third and fourth insulating layers INS3 and INS4, which are stacked on each other in the vicinity of the first via hole VIH1, may have a gentle step coverage, so that the first alignment electrode ALE1 located on the top of the first via hole VIH1 and the first horizontal power line PL1b exposed by the first via hole VIH1 can be more stably electrically connected to each other.

The above-described first conductive pattern CP1 may have a “—” shape extending along the first direction DR1, but the disclosure is not limited thereto. In some embodiments, as shown in FIG. 15B, the first conductive pattern CP1 may have a polygonal shape including a first part CP1a extending in the first direction DR1 and a second part CP1b extending in the second direction different from (or intersecting) the first direction DR1. The first alignment electrode ALE1 located on the top of the first via hole VIH1 may have a shape corresponding to the shape of the first conductive pattern CP1 in the first via hole VIH1. In an example, the first alignment electrode ALE1 may have a polygonal shape in the first via hole VIH1. The first alignment electrode ALE1 having the polygonal shape in the first via hole VIH1 may form at least two current paths. Accordingly, the contact failure of the first alignment electrode ALE1 and the first horizontal power line PL1b, which are electrically connected to each other while penetrating the first via hole VIH1, can be reduced.

In the first sub-pixel SPX1 and the second sub-pixel SPX2, the second alignment electrode ALE2 may be electrically connected to the second horizontal power line PL2b while penetrating the second via hole VIH2 of the third and fourth insulating layers INS3 and INS4, and the second horizontal power line PL2b may be electrically connected to the second conductive pattern CP2 while penetrating a second through-hole TH2 of the first and second insulating layers INS1 and INS2. In plan view, the second via hole VIH2 may be located in an area of the pixel area PXA, in which the first sub-pixel SPX1 is provided, and the second through-hole TH2 may be located in another area of the pixel area PXA, in which the second sub-pixel SPX2 is provided.

In an embodiment, the second conductive pattern CP2 may be a component added to reduce a contact failure of the second via hole VIH2, and the second horizontal power line PL2b configured with the second conductive layer CL2 and the second alignment electrode ALE2 configured with the third conductive layer CL3 in the vicinity of the second via hole VIH2. In an example, the second conductive pattern CP2 may be used as a step different compensation pattern for reducing a step difference occurring due to the second via hole VIH2 and components located on the bottom of the second alignment electrode ALE2 in the vicinity of the second via hole VIH2. As the second conductive pattern CP2 is disposed, the second via hole VIH2 and components, for example, the second conductive pattern CP2, the first and second insulating layers INS1 and INS2, the second horizontal power line PL2b, and the third and fourth insulating layers INS3 and INS4, which are stacked on each other in the vicinity of the second via hole VIH2, have a gentle step coverage, so that the second alignment electrode ALE2 located on the top of the second via hole VIH2 and the second horizontal power line PL2b exposed by the second via hole VIH2 can be more stably electrically connected to each other.

The above-described second conductive pattern CP2 may have a “—” shape extending in the first direction DR1, but the disclosure is not limited thereto. In some embodiments, as shown in FIG. 16B, the second conductive pattern CP2 may have a polygonal shape including a first part CP2a extending in the first direction DR1 and a second part CP2b extending in the second direction DR2 different from (or intersecting) the first direction DR1. The second alignment electrode ALE2 located on the top of the second via hole VIH2 may have a shape corresponding to the shape of the second conductive pattern CP2 in the second via hole VIH2. In an example, the second alignment electrode ALE2 may have a polygonal shape in the second via hole VIH2. The second alignment electrode ALE2 having the polygonal shape in the second via hole VIH2 may form at least two current paths. Accordingly, the contact failure of the second alignment electrode ALE2 and the second horizontal power line PL2b, which are electrically connected to each other while penetrating the second via hole VIH2, can be reduced.

Each of the above-described first and second conductive patterns CP1 and CP2 may be a floating pattern to which any signal and/or any voltage are/is not directly applied from the outside.

In accordance with the disclosure, via holes, and a first component configured with a first conductive layer, a second component configured with a second conductive layer, and a third component (or alignment electrode) configured with a third conductive layer in the vicinity of the via holes are located while overlapping each other, so that components stacked on each other in the vicinity of the via holes can have a gentle step coverage. Accordingly, the third component located on the top of each of the via holes and the second component exposed by a corresponding via hole are more stably electrically connected to each other, so that the reliability of the display device can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the scope of the disclosure.

What is claimed is:

1. A display device comprising:
pixels disposed on a substrate, wherein
each of the pixels includes:
a first conductive layer including a first conductive pattern, a second conductive pattern, and a third conductive pattern that are disposed on the substrate to be spaced apart from each other;
a first insulating layer and a second insulating layer that are sequentially stacked on each other on the first conductive layer;
a second conductive layer disposed on the second insulating layer, the second conductive layer including a first power line, a second power line, and a connection pattern, which are spaced apart from each other;
a third insulating layer and a fourth insulating layer that are sequentially stacked on each other on the second conductive layer;
a third conductive layer disposed on the fourth insulating layer, the third conductive layer including first alignment electrodes and second alignment electrodes, which are spaced apart from each other; and
a light emitting element disposed on the first and second alignment electrodes, and
at least one of the first alignment electrodes is electrically connected to at least one of the first conductive pattern, the second conductive pattern, and third conductive pattern.

2. The display device of claim 1, wherein:
the first insulating layer and the second insulating layer include a first through-hole, a second through-hole, and a third through-hole exposing the first conductive pattern, the second conductive pattern, and the third conductive pattern, and
the third insulating layer and the fourth insulating layer include a first via hole exposing the first power line, a second via hole exposing the second power line, and a third via hole exposing the connection pattern.

3. The display device of claim 2, wherein:
the first power line is disposed on the first conductive pattern, thereby overlapping the first conductive pattern,
the second power line is disposed on the second conductive pattern, thereby overlapping the second conductive pattern, and
the connection pattern is disposed on the third conductive pattern, thereby overlapping the third conductive pattern.

4. The display device of claim 3, wherein:
the first power line is electrically connected to the first conductive pattern while penetrating the first through-hole,
the second power line is electrically connected to the second conductive pattern while penetrating the second through-hole, and
the connection pattern is electrically connected to the third conductive pattern while penetrating the third through-hole.

5. The display device of claim 4, wherein:
each of the pixels includes a first sub-pixel, a second sub-pixel, and a third sub-pixel, and
each of the first sub-pixel, the second sub-pixel, and the third sub-pixel includes one first alignment electrode among the first alignment electrodes and two second alignment electrodes with the one first alignment electrode interposed therebetween among the second electrodes.

6. The display device of claim 5, wherein:
an area of the one first alignment electrode of the second sub-pixel is electrically connected to the first power line while penetrating the first via hole,
another area of the one first alignment electrode of the second sub-pixel is electrically connected to the connection pattern while penetrating the third via hole, and
one second alignment electrode adjacent to the second sub-pixel among the two second alignment electrodes of the first sub-pixel is electrically connected to the second power line while penetrating the second via hole.

7. The display device of claim 6, wherein the one second alignment electrode is electrically connected one of the two second alignment electrodes of the second sub-pixel.

8. The display device of claim 7, wherein the one first alignment electrode of the second sub-pixel is electrically connected to the third conductive pattern through the third via hole, the connection pattern, and the third through-hole.

9. The display device of claim 7, wherein:
the third conductive pattern includes a first part extending in a first direction and a second part extending in a second direction different from the direction in which the first part extends, and
the one first alignment electrode in the third via hole has a shape corresponding to the first part and the second part of the third conductive pattern.

10. The display device of claim 9, wherein:
each of the first sub-pixel, the second sub-pixel, and the third sub-pixel includes a lower metal pattern configured with the first conductive layer and an upper electrode configured with the second conductive layer, the upper electrode being disposed on the lower metal pattern with the first and second insulating layers interposed therebetween, and
the lower metal pattern and the upper electrode constitute a storage capacitor.

11. The display device of claim 10, wherein the third conductive pattern is integrally formed with the lower metal pattern of the second sub-pixel.

12. The display device of claim 7, wherein the one first alignment electrode of the second sub-pixel is electrically connected to the first conductive pattern through the first via hole, the first power line, and the first through-hole.

13. The display device of claim 12, wherein the one first alignment electrode in the first via hole has a shape corresponding to the first conductive pattern.

14. The display device of claim 13, wherein the first conductive pattern includes a first part extending in a first direction and a second part extending in a second direction different from the first direction.

15. The display device of claim 7, wherein the one second alignment electrode of the first sub-pixel is electrically connected to the second conductive pattern through the second via hole, the second power line, and the second through-hole.

16. The display device of claim 15, wherein the one second alignment electrode in the second via hole has a shape corresponding to the second conductive pattern.

17. The display device of claim 16, wherein the second conductive pattern includes a first part extending in a first direction and a second part extending in a second direction different from the first direction.

18. The display device of claim 1, wherein each of the first conductive pattern and the second conductive pattern is a floating pattern.

19. The display device of claim 1, wherein
each of the pixels further includes:
a bank disposed on the first alignment electrodes and the second alignment electrodes;
a fifth insulating layer disposed over the bank, the fifth insulating layer including a first contact hole exposing an area of the first alignment electrode and a second contact hole exposing an area of the second alignment electrode;
an insulating pattern disposed on the fifth insulating layer, the insulating pattern exposing a first end portion and a second end portion of the light emitting element; and
a fourth conductive layer including a first electrode and a second electrode, which are disposed on the insulating pattern to be spaced apart from each other, and
the first electrode is electrically connected to the first alignment electrode while penetrating the first contact hole, and
the second electrode is electrically connected to the second alignment electrode while penetrating the second contact hole.

20. A display device comprising:
a substrate including a display area and a non-display area; and
at least one pixel disposed in the display area, the at least one pixel including a first sub-pixel, a second sub-pixel, and a third sub-pixel each including an emission area and a non-emission area, wherein
the pixel includes:
a first insulating layer, a second insulating layer, a third insulating layer, and a fourth insulating layer that are sequentially stacked on each other on the substrate;
a first conductive pattern, a second conductive pattern, and a third conductive pattern that are disposed between the substrate and the first insulating layer, the first conductive pattern, the second conductive pattern, and the third conductive pattern being spaced apart from each other;
a semiconductor layer disposed between the first insulating layer and the second insulating layer;
a first power line, a second power line, and a connection pattern, that are disposed between the second insulating layer and the third insulating layer, the first power line, the second power line, and the connection pattern, being spaced apart from each other;
a first alignment electrode and a second alignment electrode disposed on the fourth insulating layer, the first alignment electrode and the second alignment electrode being spaced apart from each other;
a light emitting element disposed on the first alignment electrode and the second alignment electrode in at least the emission area; and
a first electrode and a second electrode disposed on the light emitting element, the first electrode and the second electrode being electrically connected to the light emitting element,
the first insulating layer and the second insulating layer include a first through-hole exposing the first conductive pattern, a second through-hole exposing the second conductive pattern, and a third through-hole exposing the third conductive pattern,
the third insulating layer and the fourth insulating layer include a first via hole exposing the first power line, a second via hole exposing the second power line, and a third via hole exposing the connection pattern, and
the first alignment electrode is electrically connected to at least one of the first conductive pattern, the second conductive pattern, and the third conductive pattern.
